(19) United States
(12) Patent Application Publication
(10) Pub. No.: US 2026/0349034 A1
(43) Pub. Date: Nov. 5, 2026

(54) MULTI-DIMENSIONAL HARDWARE FUZZING WITH FEDERATED SCREENING

(71) Applicants: Bryan Hunt, McCall, ID (US); Marcos E. Carranza, Portland, OR (US); Richard Marin Benavides, Heredia (CR); Garrett Clay, Beaverton, OR (US); Krishna Surya, Beaverton, OR (US)

(72) Inventors: Bryan Hunt, McCall, ID (US); Marcos E. Carranza, Portland, OR (US); Richard Marin Benavides, Heredia (CR); Garrett Clay, Beaverton, OR (US); Krishna Surya, Beaverton, OR (US)

(21) Appl. No.: 19/720,708

(22) Filed: Jun. 25, 2026

(51) Int. Cl. G01R 31/319; G01R 31/3181

(52) U.S. Cl. CPC G01R 31/31917; G01R 31/31813

(57) ABSTRACT

Various aspects are disclosed for testing a device with multidimensional fuzzing of hardware-based parameters. An example method includes parameter fuzzing to produce mutated parameter values, for a semiconductor device under test, in multiple dimensions that correspond to multiple configurable interfaces of the semiconductor device. The method generates a test sequence that includes the mutated parameter values to invoke the multiple configurable interfaces and change operation of the semiconductor device. The method communicates the test sequence to the semiconductor device to concurrently control the multiple configurable interfaces during the test sequence, and obtains a test result from the execution of the test sequence on the semiconductor device. The method classifies the test result as a hard failure, a soft anomaly, or a pass, and performs additional parameter fuzzing to test additional mutated parameter values in a subsequent test sequence.

### BACKGROUND

Modern integrated circuits, including but not limited to processors, graphics processing units, hardware accelerators, memory controllers, and network application-specific integrated circuits, contain multiple functional units fabricated on a single die. Each functional unit, or intellectual property (IP) block, implements a defined capability, such as a vector execution unit, a cache controller, power management logic, or an interconnect. These devices operate at high concurrency and integrate heterogeneous execution units that interact with firmware, configuration state, power management logic, and workload timing during operation.

These devices are commonly verified and tested across multiple stages of a development and production lifecycle. Pre-silicon verification exercises a register-transfer-level (RTL) model of the design through simulation, hardware emulation, or virtual prototyping. Post-silicon validation exercises physical silicon during bring-up and qualification. High-volume manufacturing applies screening to production units, and units returned from the field are subjected to failure analysis. At each stage, test content is executed against the device, and the resulting behavior is observed to determine whether the device operates within its specification.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate, generally, by way of example, but not by way of limitation, various embodiments discussed in the present document.

FIG. 1 illustrates a conceptual diagram of an example multi-dimensional state space for silicon failures and an accompanying testing process.

FIG. 2 illustrates a workflow diagram of an example process for multi-dimensional hardware fuzzing of a semiconductor device.

FIG. 3 illustrates a block diagram of an example system architecture for multi-dimensional fuzzing of a semiconductor device with screening testing.

FIG. 4 illustrates nodes and edge types of a knowledge graph used with screening testing.

FIG. 5 depicts an example operational flow for mutating parameters in a subsequent test sequence in connection with multi-dimensional fuzzing techniques.

FIG. 6 depicts a flowchart of an example method for testing a semiconductor device using multi-dimensional parameter fuzzing techniques.

FIG. 7A provides an overview of example components deployed at a computing device.

FIG. 7B provides a further overview of example components within a computing device.

### DETAILED DESCRIPTION

The following discusses approaches for the automated testing of integrated circuits. Some examples pertain to generating and executing test sequences that span multiple configurable interfaces of a semiconductor device, including instructions, configuration registers, and power states, to detect failures and anomalies. Some examples also include engines and architectures to implement post-silicon validation challenges using multi-dimensional fuzzing on a semiconductor device under test, to detect failures or anomalies in connection with the device under test.

Automated test generation techniques generally include the use of transformations to test different types and combinations of inputs and observe the resulting behavior. Fuzzing is one such technique used in testing, in which target device inputs are generated and mutated, delivered to the target device, and evaluated against monitored responses to identify failures. In the context of hardware interfaces, fuzzing can involve the automated generation and execution of instruction sequences on a device, as the device is monitored for incorrect behavior.

Disclosed in some examples are methods, devices, systems, and machine-readable media that test a semiconductor device by generating and executing test sequences that span multiple configurable interfaces of the device simultaneously, while also storing test sequences that produce failures in a corpus that is shared across testing sites. In some examples, upon detection of a failure or anomaly during execution of a test on a semiconductor device, the failure may be mapped to one or more functional units of the device, and a test campaign targeting the one or more functional units may be configured. The test sequences may be generated to mutate across multiple interface types in a single mutation operation, such that a given test sequence varies one or more instructions, one or more configuration register values, and one or more power states together. This mutation can expose interactions among interfaces that single-interface testing does not reach.

In some implementations, the generated test sequences are executed on the device, and the resulting execution behavior is classified, for example, as a hard failure, a soft anomaly, or a pass, using one or more detection techniques such as comparison against a reference, repeated execution to detect non-deterministic results, comparison against statically computed expected values, detection of faults and hangs, and monitoring of telemetry. In some implementations, upon detection of a failure, a device state associated with the failure is captured to enable re-execution of the test sequence under a defined configuration. A captured test sequence may be reduced by iteratively removing portions of the sequence and re-executing the remainder to obtain a shorter sequence that produces the failure.

In some implementations, test sequences that produce failures are scored along one or more axes, such as reproducibility, severity, coverage of functional units, uniqueness, and minimality. These test sequences are stored in the corpus and are tagged with metadata describing the associated functional unit, device product, device stepping, failure type, and configuration context. In some implementations, the corpus may be queried for stored test sequences matching a target device configuration, and the matching test sequences may be delivered for execution on the target device, either through a live query or as an exported bundle for execution in an environment without connectivity to the corpus. In some implementations, the corpus may also seed subsequent test campaigns with stored test sequences, such that test generation is biased toward functional units and interface states associated with previously recorded failures.

Modern data center processors operate at an extreme scale, with high concurrency, heterogeneous execution units, and complex interactions among firmware, configuration, power management, and workload timing. Many silicon failures manifest only under rare, multi-dimensional combinations of these variables, often after prolonged operation. As a result, post-silicon failures are increasingly difficult to reproduce, diagnose, and prevent from escaping into production.

Although many types of testing approaches are in use, limitations occur with common testing approaches. Screening tools can miss cross-interface failure modes because most screening tools exercise individual interfaces (e.g., instructions or configuration registers) in isolation. Often, real-world failures emerge only from interactions across multiple interfaces, such as instruction sequences that become unsafe under specific power transitions or configuration states. Multi-interface tools often sacrifice depth for breadth, missing rare, multi-dimensional corner cases.

Common testing approaches also may lack the capability to automatically pivot from detection to targeted stress. When failures or anomalous signals are detected, there is not an automated mechanism to translate those observations into focused stress testing of the suspected logic. Engineers must manually infer which IP block (e.g., a discrete, identifiable functional unit of silicon design implementing a specific capability, such as a vector execution unit, cache controller, power management logic, or interconnect) or state spaces to explore, resulting in slow, subjective, and unscalable workflows. Consequently, early indicators of failure (such as soft signals, warnings, hardware-register outliers, near-miss events, timing skews, or thermal anomalies) are often ignored rather than amplified into targeted reproduction and screening. Proven failure sequences are also rarely shared systematically across teams or sites. Duplicated effort and inconsistent coverage occur without a federated model for building and evolving a shared, IP-tagged library of effective screening sequences.

Without standardized IP-level tagging and metadata, screening remains broad and static. Tools do not dynamically compose or filter screening content based on risk, relevance, or observed failure domains. Without per-IP failure breadth statistics across units, lots, and steppings, it is typically not possible to distinguish design bugs (systematic failures reproducible across all units of a stepping) from manufacturing process errors (failures clustered to specific lots or wafer regions) from random manufacturing defects (low-rate failures distributed stochastically across units). These distinctions matter for root-cause triage and yield improvement.

Common testing approaches are often slow, fragile, or unable to reproduce failures. Validation and design teams encounter failures during bring-up and qualification that cannot be reliably reproduced, leading to sightings that remain unresolved or are incorrectly closed. Failure Analysis Correlation Requests (FACRs) and Problem Response Teams (PRTs) frequently spend weeks or months attempting to reproduce failures escalated from the field or production lines. Many issues are never deterministically reproduced due to missing signals, environmental sensitivity, or non-deterministic behavior. This delays root-cause isolation and increases escape risk at every stage from pre-production validation through high-volume manufacturing.

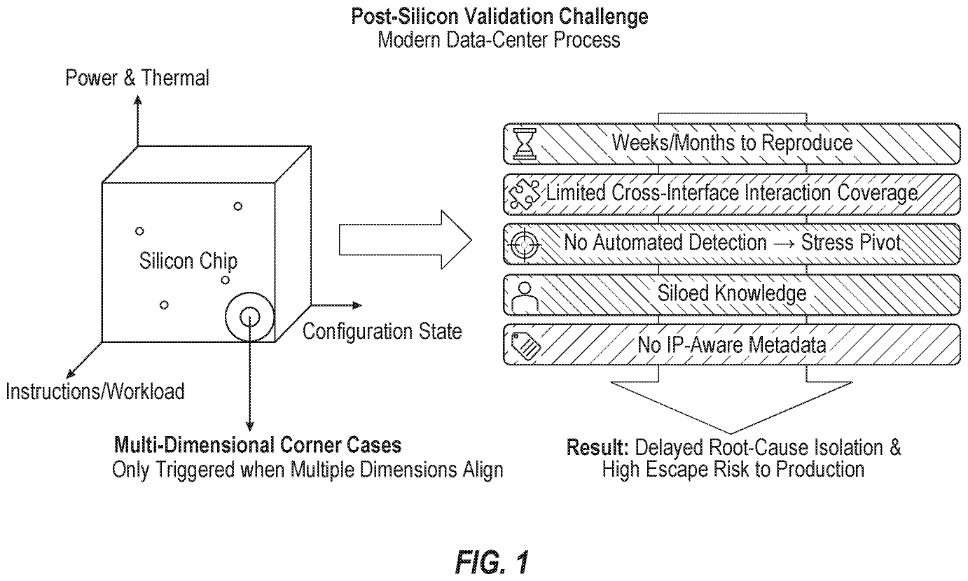

FIG. 1 illustrates a conceptual diagram of an example multi-dimensional state space in which silicon failures occur and the resulting consequences for a testing process. In this diagram, a state space of a silicon chip is represented as a three-dimensional volume bounded by three axes. A first axis represents instructions or workload applied to the silicon chip. A second axis represents the configuration state of the silicon chip. A third axis represents the power and thermal conditions of the silicon chip. Points distributed within the volume represent individual operating conditions defined by a combination of values along the three axes.

A region within the volume, shown as a multi-dimensional corner case, represents an operating condition at which a failure is triggered only when values along multiple axes align concurrently. Three axes are presented as one example for clarity. In some examples, the state space includes a higher number of dimensions. Each dimension may correspond to a configurable interface of the device, such that a failure may be triggered only when a specific combination of values across a subset of those dimensions occurs simultaneously.

FIG. 1 also depicts a set of conditions that follow from the difficulty of locating the multi-dimensional corner case within the state space. A first condition represents a duration, on the order of weeks or months, to reproduce a failure. A second condition represents limited coverage of interactions across multiple interfaces of the device. A third condition represents an absence of an automated transition from the detection of a failure to stress testing directed at the source of the failure. A fourth condition represents knowledge of failures being retained within individual teams or sites rather than being shared. A fifth condition represents an absence of metadata associating test content with individual functional units of the device. These conditions often lead to a result that includes delayed isolation of a root cause and an increased likelihood of a failure reaching production.

As already noted, some common approaches attempted for system testing include: manual, trial-and-error reproduction by engineers; static test suites with no adaptive feedback; and validation and screening tools, including bring-up and qualification suites as well as high-volume screening tools, which rely on fixed, pre-authored test content per IP block. These tools do not adapt based on observed failures, cannot target newly identified failure domains, and provide no mechanism to evolve coverage in response to discovered issues. Additionally, pre-generated instruction fuzzers are not failure-directed or federated. Software fuzzing frameworks are designed to target software APIs and do not have the capability to target silicon interfaces. Pre-silicon constrained-random verification against RTL models is limited to the design space covered by the RTL model, and does not produce reusable failure sequences applicable to physical silicon screening.

Unlike these approaches, the present implementations automatically pivot from observed failures or anomalies to targeted, multi-dimensional fuzzing across the silicon lifecycle, usable from pre-silicon validation through high-volume manufacturing and fleet screening. This fuzzing is enabled while simultaneously building and sharing an evolving IP-tagged corpus that enables statistical identification of design bugs, manufacturing process errors, and random manufacturing defects across deployments. The present mechanisms can be used to perform variations of multi-dimensional fuzzing, which spans instructions, hardware registers (MSRs, MMIO, PCIe), configuration knobs, power states, and the like, across silicon interfaces. As a result, these mechanisms can be used for a variety of central processing unit (CPU) devices, graphics processing unit (GPU) devices, System-on-Chip (SoC) devices, and the like.

The presently disclosed mechanisms include a fuzzing engine to discover and reproduce failures, and a screening engine to deploy proven test sequences at high-volume manufacturing scale. In various examples, the fuzzing engine and the screening engine are operated in at least the following three modes.

1.) Failure-Directed Fuzzing Mode. Upon detecting a hard failure (e.g., a crash, a hang, an exception, or a machine-check error) or soft anomaly (e.g., a timing, power, thermal, or telemetry deviation, such as unexpected latency, anomalous warning, near-miss, abnormal thermal behavior) in any screening tool, the testing automatically pivots to targeted fuzzing of the suspect IP block. This approach takes a single, rare failure signal and fuzzes around it, mutating and exploring the nearby instruction/configuration space, to amplify it into a reliably reproducible sequence and simplify it to a minimal trigger, with full state capture enabling deterministic replay. This mode is designed for medium-duration targeted campaigns, although this mode may be shortened for environments with minimal time budgets.

2.) Exploratory Fuzzing Mode. Proactively fuzzes IP blocks to discover unknown failures under pre-defined guardrails. This mode is designed for long-duration campaigns targeting part-specific manufacturing defects or systemic validation issues.

3.) Federated Screening Mode. Queries the Global Corpus for top-scored, proven failure sequences matching a given product, CPU ID, or stepping, and executes them as a targeted screening package for efficient, at-scale deployment. This mode is designed for short-duration screening runs using proven, effective sequences.

Across these three modes, successful failure sequences may be tagged by IP block, scored, and distributed across teams for federated screening at scale. The shared corpus continuously evolves as new sequences are discovered, mutated, and proven effective, becoming more potent over time rather than static.

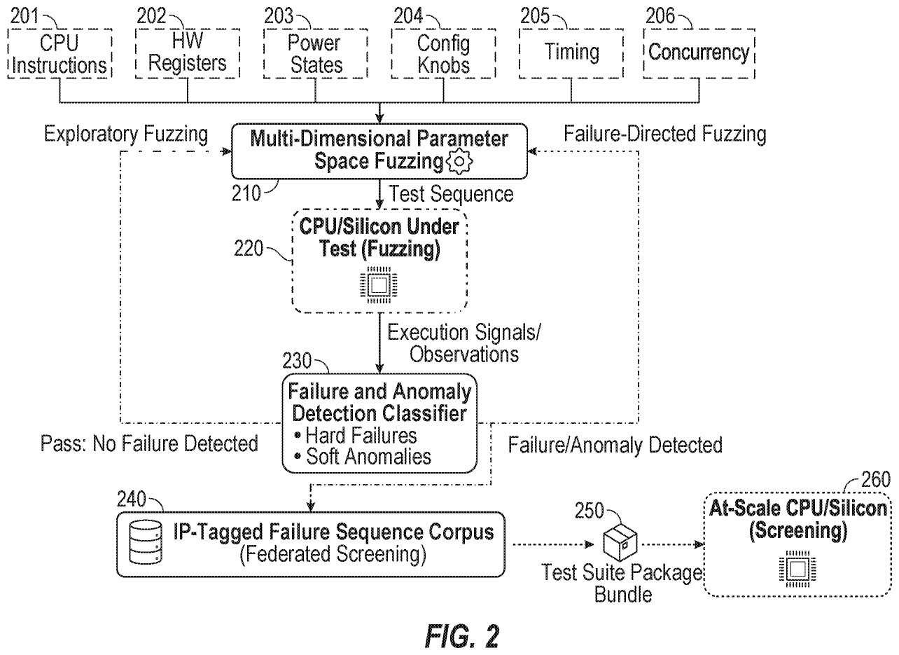

FIG. 2 illustrates a workflow diagram of an example process for multi-dimensional hardware fuzzing of a semiconductor device with failure-directed and exploratory operation and federated reuse of failure sequences. This diagram depicts multiple parameter sources that define different dimensions of a parameter space exercised during fuzzing.

CPU instructions 201 represent a dimension corresponding to instructions executed by the device under test. HW registers 202 represent a dimension corresponding to hardware registers of the device under test, such as model-specific registers, memory-mapped input/output registers, and peripheral component interconnect express registers. Power states 203 represent a dimension corresponding to idle states and performance states of the device under test. Config knobs 204 represent a dimension corresponding to software-visible control values that enable or disable features of the device under test. Timing 205 represents a dimension corresponding to relative timing among operations applied to the device. Concurrency 206 represents a dimension corresponding to concurrent execution conditions of the device under test. The illustrated dimensions are non-limiting examples, and additional dimensions or alternative parameter sources may be included.

Each of CPU instructions 201, HW registers 202, power states 203, config knobs 204, timing 205, and concurrency 206 feeds into the multi-dimensional parameter space fuzzing component 210, so that test content spans multiple parameter sources concurrently. By generating test content that spans multiple dimensions concurrently, this workflow can discover cross-interface failure modes that single-dimensional testing does not reach.

The multi-dimensional parameter space fuzzing component 210 generates a test sequence from a combination of values drawn from the parameter sources. The multi-dimensional parameter space fuzzing component 210 operates according to a selected mode. In an exploratory fuzzing mode, indicated by the exploratory fuzzing path, the multi-dimensional parameter space fuzzing component 210 generates test content across a range of the parameter space without requiring a prior failure. In a failure-directed fuzzing mode, indicated by the failure-directed fuzzing path, the multi-dimensional parameter space fuzzing component 210 generates test content directed toward a region of the parameter space associated with a detected failure or anomaly. This may occur, for example, by constraining the parameter space to a functional unit and state domain associated with the detected failure or anomaly. Constraining the parameter space in this manner can reduce the time to reproduce a failure relative to exercising the parameter space without such a constraint, and can increase efficiency and coverage with respect to the functional unit and state domain of interest.

The test sequence generated by the multi-dimensional parameter space fuzzing component 210 is provided to the device under test (e.g., CPU or silicon under test 220). The CPU or silicon under test 220 executes the test sequence and produces execution signals and observations, such as architectural state, fault indications, and telemetry. The execution signals and observations are provided to the failure and anomaly detection classifier 230.

The failure and anomaly detection classifier 230 evaluates the execution signals and observations and classifies an outcome of the executed test sequence. In some examples, the failure and anomaly detection classifier 230 classifies the outcome as one of a hard failure, a soft anomaly, or a pass. A hard failure represents a violation of architectural correctness, such as a crash, a hang, an exception, or an uncorrectable machine-check error. A soft anomaly represents a non-fatal deviation from expected behavior, such as a timing, power, thermal, or telemetry deviation, and may include correctable machine-check errors.

When the failure and anomaly detection classifier 230 classifies the outcome as a pass (no failure detected), the outcome is returned to the multi-dimensional parameter space fuzzing component 210, which generates a further test sequence, forming a feedback loop. When the failure and anomaly detection classifier 230 classifies the outcome as a failure or anomaly (failure or anomaly detected), the outcome is returned to the multi-dimensional parameter space fuzzing component 210 to direct generation of further test sequences toward the detected condition. By directing generation toward a detected condition and iterating across multiple dimensions, the workflow can refine a rare or one-off failure into a simpler and more repeatable failure.

The failure and anomaly detection classifier 230 also provides a test sequence associated with a detected failure or anomaly to the IP-tagged failure sequence corpus 240. The IP-tagged failure sequence corpus 240 stores test sequences associated with failures or anomalies, and may be tagged with metadata such as a functional unit identifier, a product identifier, a configuration identifier, a severity, a score, and a stepping identifier. The IP-tagged failure sequence corpus 240 represents an evolving library of failure sequences that can be shared across teams and sites, can support identification and tracking of failures across teams and sites, and can provide a structured record for use in root-cause reporting and failure triage. In some examples, the IP-tagged failure sequence corpus 240 is a federated corpus shared among multiple sites, to reveal common inputs that produce failures across multiple systems as discussed below. In some examples, the IP-tagged failure sequence corpus 240 can also store configuration values observed to suppress a failure, which can inform a software workaround or a guard-band recommendation while a hardware change is developed.

Selected test sequences from the IP-tagged failure sequence corpus 240 are assembled into a test suite package bundle 250. The test suite package bundle 250 represents a curated set of stored test sequences packaged for delivery, for example, as a versioned set deliverable to an environment without connectivity to the corpus. The test suite package bundle 250 is provided to the at-scale CPU or silicon screening component 260. The at-scale CPU or silicon screening component 260 executes the test sequences of the test suite package bundle 250 against production units, applying stored failure sequences as screening content at scale.

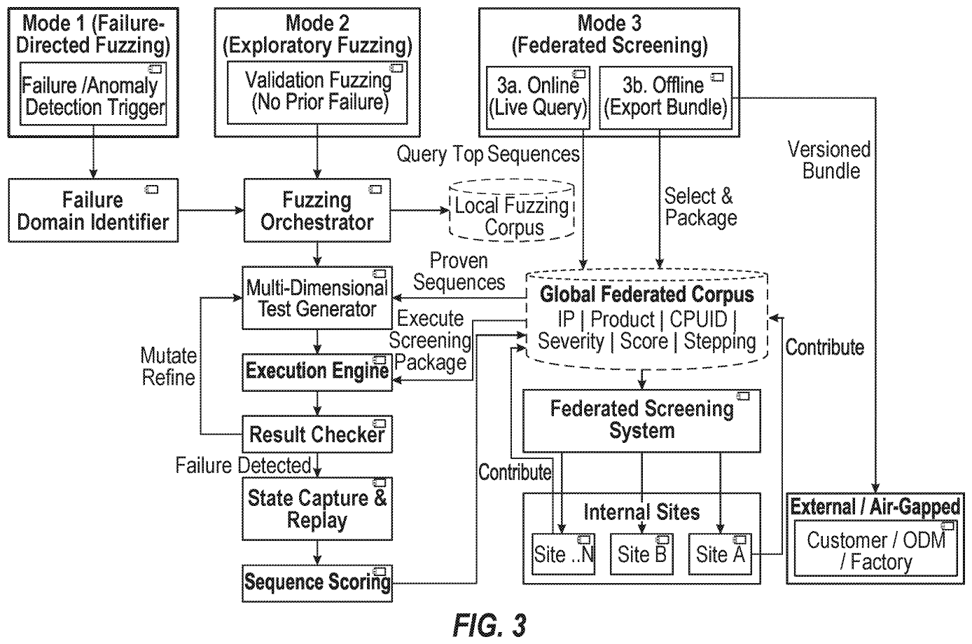

FIG. 3 illustrates a block diagram of an example system architecture for multi-dimensional fuzzing of a semiconductor device with federated screening. As shown, the system operates in three modes.

Mode 1 includes a failure or anomaly detection trigger that initiates failure-directed fuzzing in response to a detected condition. In Mode 1, upon detecting a failure or anomaly, the system automatically pivots to targeted fuzzing of the suspect IP block(s), mutating parameter configurations around the observed condition to amplify and reproduce the issue.

Mode 2 includes a validation fuzzing component that initiates exploratory fuzzing without a prior failure. This exploratory fuzzing proactively fuzzes silicon IP blocks without requiring prior failures, providing broad, continuous coverage.

Mode 3 includes a federated screening function having an online sub-mode that submits a live query and an offline sub-mode that produces an export bundle. Federated screening can be used to distribute proven sequences across teams, sites, cluster nodes, and system cores, with smart filtering by IP block, SKU, and failure type. Sites can query the corpus for targeted screening packages and contribute their own discoveries back, creating a shared corpus that continuously evolves and grows more potent over time. The online sub-mode can include querying the Global Federated Corpus for top-scored sequences matching the target system (product, CPUID signature, stepping) and executing them directly. The offline sub-mode can include packaging a curated, versioned snapshot of sequences into a self-contained bundle for delivery to customers, ODMs, or air-gapped factory environments, without exposing corpus internals or requiring connectivity.

Consistent with the flows of FIG. 3, in failure-directed operation, the failure or anomaly detection trigger of Mode 1 provides a detected condition to a failure domain identifier. The failure domain identifier maps the detected condition to one or more functional units of the device and groups related failures into a failure domain. The failure domain identifier provides the one or more identified functional units to a fuzzing orchestrator. In an exploratory operation, the validation fuzzing component of Mode 2 provides input to the fuzzing orchestrator without first passing through the failure domain identifier. The fuzzing orchestrator configures a fuzzing campaign directed at the identified functional units and maintains a local fuzzing corpus that records test sequences previously generated by the fuzzing orchestrator.

When a failure or anomaly is detected, the failure domain identifier maps the failure signature to one or more suspect IP blocks, then classifies it into a failure domain, which is a cluster of failures believed to share a single root cause. IP block mapping uses multiple heuristics: the faulting instruction's opcode identifies the execution unit (e.g., FPU, vector unit, integer ALU), the faulting MSR address range identifies the configuration domain (e.g., power management, thermal, prefetcher), and the exception vector or machine-check bank identifies the hardware source. For soft anomalies (including but not limited to thermal warnings), the sensor location maps directly to the physical IP block. The output is a set of candidate IP blocks ranked by confidence.

The failure domain identifier may also deduplicate across failures. Domain classification uses a feature vector derived from the failing sequence: the set of instruction classes present, the IP blocks exercised, the CPUID features required, the register file regions touched, and any anomalous telemetry signatures (thermal, timing). Two failures are assigned to the same domain if their feature vectors fall within a configurable similarity threshold. This prevents the corpus from being filled with thousands of superficially different sequences that all trigger the same underlying failure and ensures that future fuzzing campaigns target genuinely distinct failure regions rather than over-saturating a single known bug.

The fuzzing orchestrator directs a multi-dimensional test generator to generate test sequences that span multiple interfaces of the device. Given a set of target IP blocks, the fuzzing orchestrator configures a multi-dimensional fuzzing campaign targeting one or more systems. Configuration may include, for example: selecting the instruction families relevant to the target IP (e.g., AVX-512 for vector unit, AMX for matrix engine), defining the MSR ranges to mutate, choosing which config knobs to vary (XCR0 feature bits, PKRU keys, PMU event selectors), and optionally including power state transitions (C-state entry/exit, P-state changes). The orchestrator also determines whether to seed the campaign from the corpus (using proven sequences targeting the same IP) or to start from nothing. It manages campaign lifecycle including start, monitor, stop, and resource allocation across available cores or rack/cluster nodes. It utilizes its own local fuzzing corpus to track previously tried sequences. Only proven failure sequences are published to the Global Federated Corpus.

The multi-dimensional test generator provides the generated test sequences to an execution engine, which executes the test sequences on the device. The multi-dimensional test generator produces test sequences that span multiple silicon interfaces simultaneously. Mutation strategies are utilized to slightly mutate tests from one to another. The generator operates according to the supported modes: failure-directed mutation around observed conditions in Mode 1, broad exploratory mutation in Mode 2, and corpus-seeded execution or refinement of proven sequences in Mode 3. Mutations are likely to span across multiple interface types, where a single mutation operation might change an instruction, an MSR value, and a power state simultaneously, discovering cross-interface interactions that single-dimensional tools miss.

The execution engine provides execution results to a result checker, which classifies an outcome of each test sequence. The execution engine executes test sequences on physical silicon and classifies outcomes based on observed execution behavior and detected deviations. Runtime monitoring and detection assists (including architectural state validation and hardware lockstep, where available) provide evidence for classification. When the result checker does not detect a failure, the result checker returns the outcome to the multi-dimensional test generator, which mutates and refines a test sequence, forming a feedback loop. When the result checker detects a failure, the result checker provides the test sequence to a state capture and replay component, which records device state associated with the failure to support re-execution.

In an example, each execution is classified as one of the following:

1) Hard Failure: Violation of architectural correctness, miscompare, including crashes, hangs (e.g., watchdog timeouts), CPU exceptions, or uncorrectable machine-check errors;
2) Soft Anomaly: Non-fatal deviations from expected behavior that preserve architectural correctness but indicate silicon marginality or reduced robustness. This includes threshold-based deviations (e.g., timing, power, thermal, telemetry, and correctable machine-check errors) and reference-based deviations identified via temporal comparison (the same IP instance under identical context across time exhibiting statistically significant signal differences) and spatial comparison (equivalent IP instances under identical context exhibiting statistically significant signal differences); or
3) Pass: Recorded when no hard failures or soft anomalies are detected.

Events detected via architectural consistency checks or hardware lockstep are classified as hard failures or soft anomalies according to impact, using the definitions above.

In an example, upon any failure or soft anomaly, the state capture and replay component logs the complete CPU/APU state: the full instruction sequence that was executing, all MSR values, CPU flags (RFLAGS), general-purpose and vector register contents, memory contents at referenced addresses, CPUID configuration, XCR0/PKRU state, and the instruction pointer at the point of failure; and relevant environmental and telemetry context observed during execution, such as temperature, voltage, power, frequency, and selected performance-monitoring and sensor readings. This captured state enables deterministic replay, meaning the exact sequence can be re-executed with the exact configuration to reproduce the failure on demand. The system can also automatically explore alternative replay configurations to find simpler or faster reproduction paths (e.g., does the failure still occur with a shorter instruction prefix? Does the failure occur with a different memory alignment? etc.).

A sequence scoring component scores the test sequence along one or more axes. In an example, each failure sequence is evaluated on multiple axes: reproducibility (what percentage of replays trigger the failure ranging from 0.01 for rare to 1.0 for deterministic), severity (hard crash>hang>soft anomaly>timing deviation), IP coverage, uniqueness, and minimality. The composite score determines the sequence's priority in the corpus and its ranking in screening packages.

A scored test sequence is provided to a global federated corpus that stores test sequences tagged with metadata, including a functional unit identifier, a product identifier, a CPUID signature, a severity, a score, and a stepping identifier. The global federated corpus also provides proven test sequences back to the multi-dimensional test generator to seed subsequent campaigns. The global federated corpus exchanges test sequences with a federated screening system and a set of internal sites, shown as Site A, Site B, through Site N, each of which queries the global federated corpus for top-scored test sequences and contributes test sequences back to the global federated corpus. In Mode 3 online operation, a query for top-scored test sequences is submitted to the global federated corpus and a returned screening package is executed by the execution engine. In Mode 3 offline operation, test sequences are selected and packaged from the global federated corpus as a versioned bundle that is delivered to an external or air-gapped environment, shown as a customer, original design manufacturer, or factory, for execution without connectivity to the global federated corpus.

A fuzzing workflow may be repeated with the following operations. The core loop shown in FIG. 3 (involving Modes 1 and 2) proceeds as follows: the Fuzzing Orchestrator configures a multi-dimensional fuzzing campaign targeting the identified IP block(s). The Multi-Dimensional Test Generator generates and mutates test sequences spanning multiple silicon interfaces simultaneously, including instructions, Hardware Registers (MSRs, MMIO, PCIe, etc.), CPUID leaves, XCR0 feature bits, PKRU configurations, PMU events, cache states, and power states. These sequences are executed on silicon by the Execution Engine and evaluated by the Result Checker, which monitors for crashes, hangs, incorrect state, flag mismatches, timing deviations, and thermal anomalies.

When a failure is detected, the State Capture & Replay component logs the full CPU/APU state (instruction sequence, MSR values, flags, memory) to enable deterministic replay. The Sequence Scoring component then evaluates the failure sequence by reproducibility, severity, IP coverage, and uniqueness of the failure mode. Proven sequences are stored in the Global Federated Corpus, which is an evolving database where each entry is tagged with IP block, product/SKU, CPUID signature, failure type, severity, reproducibility score, configuration context, and stepping (or any relevant metadata).

When no failure is detected, the Multi-Dimensional Test Generator mutates the sequence and retries, forming a feedback loop. The corpus also seeds future fuzzing campaigns with proven sequences, enabling evolutionary improvement.

As part of replay analysis, the system may selectively vary software-visible configuration and execution parameters while holding the primary failure stimulus constant in order to identify conditions under which a previously observed failure does not manifest.

Configuration combinations that suppress or avoid failure are recorded as mitigation candidates associated with the same failure domain. These mitigation candidates can inform temporary software workarounds, guard-band recommendations, or operational guidance while permanent hardware fixes are under development. A mitigation technique can be appropriately tagged and sent to the Global Federated Corpus for scoring.

In further examples, various types of sequence minimization may be implemented. Failing sequences produced by the generator are often longer than necessary. For example, a 500-instruction sequence may fail due to a 12-instruction interaction within. The sequence minimization may apply delta-debugging reduction by iteratively removing sub-sequences (by halving, then quarter-splitting) and re-executing the remainder on the device under test, preserving only instructions required to reproduce the failure. The output is the shortest sequence that still triggers the same failure domain. Minimized sequences are cheaper to execute during screening, easier for engineers to analyze during debug, and produce higher-fidelity corpus entries. The minimality scoring dimension in the corpus data model is utilized to score minimized sequences.

A corpus data model may be established to define multiple types of data fields. In one example, each corpus entry contains the following fields:

TABLE 1

| Field | Description | Example |
|---|---|---|
| Sequence ID | Unique Identifier GUID | a3f8c1b2-7d4e-4f9a-b6e1- |
| | | 2c8d5a9f0e3b |
| Instruction Sequence | Serialized test sequence | <test sequence> |
| IP Block | Target IP Block(s) | FPU, Vector |
| Product | Product name | GNR |
| CPUID Signature | Family/Model/Stepping | Family 6, Model 0xAD, |
| | CPUID(s) supported | Stepping 0xB0 |
| Required CPUID Features | Minimum CPUID feature | AVX512F, AVX512BW, |
| | flags needed to execute this | AMX-BF16, AMX-TILE |
| | sequence | |
| Required MSR Access | MSRs the sequence | true |
| | reads/writes (must be | |
| | accessible) | |
| Required Privilege Level | Ring 0/3/mixed | Ring3 |
| Failure Type | Classification of the failure | Hang |
| Severity | Hard failure/ Soft Failure / | Hard |
| | Timing | |
| Reproduction Score | 0-1 | 0.94 |
| Execution Speed | Time to execute test | 10 microseconds |
| Complexity | Number of dimensions | 4 (instructions + MSRs + |
| | involved | XCR0 + P-State) |
| Failure Breadth | % of units that reproduce this | 0.32 GNR-B0 |
| | per Product/Stepping | |
| Configuration Context | MSR values, XCR0, P-state, | {XCR0: 0xE7, Pstate: max, |
| | etc. | . . .} |
| Captured Pre-Failure State | CPU state snapshot captured | (binary blob) |
| | immediately before the | |
| | failing instruction or event, | |
| | enabling before/after | |
| | comparison with the captured | |
| | failure state. | |
| Captured Failure State | Full CPU state snapshot after | (binary blob) |
| | failure (not available in hard | |
| | hang scenarios) | |
| Discovery Source | Site/tool/date | Site-A / ToolA / 2026 Mar. 1 |
| Parent Sequence | If this sequence was derived | 7e2b4d91-0c6f-4a3e-8f15- |
| | by mutation from another, the | d4a7b9c2e6f8 |
| | Sequence ID of the | |
| | originating sequence. | |
| Schema Version | Corpus Schema version when | v16 |
| | added | |
| Tags | Further searchable metadata | AVX512, thermal, turbo |
| Mitigation Conditions | Configuration settings | XCR0: disable ZMM state, |
| (optional) | observed to suppress the | P-state: limit to non-turbo, |
| | failure | MSR_IA32_MISC_ENABLE: |
| | | turbo_disabled |

As will be understood, the schema in TABLE 1 is a basic data schema that can be expanded or changed for additional types of hardware domains.

In many examples, the test generator does not select instructions purely at random. While mutations incorporate randomness, the generation and selection of a test is guided by a structured representation of relationships. For example, a selection can operate over a structured representation of relationships between instructions, IP blocks, silicon configuration state, and historical failure data. This structured representation encodes which instructions execute on which hardware units, which features must be enabled, which configuration registers govern each domain, and which sequences have previously triggered failures.

One example of the structured representation uses a knowledge graph with typed nodes and edges. Other implementations, such as constraint databases, grammar-based generators, or rule engines, may express the same relationships.

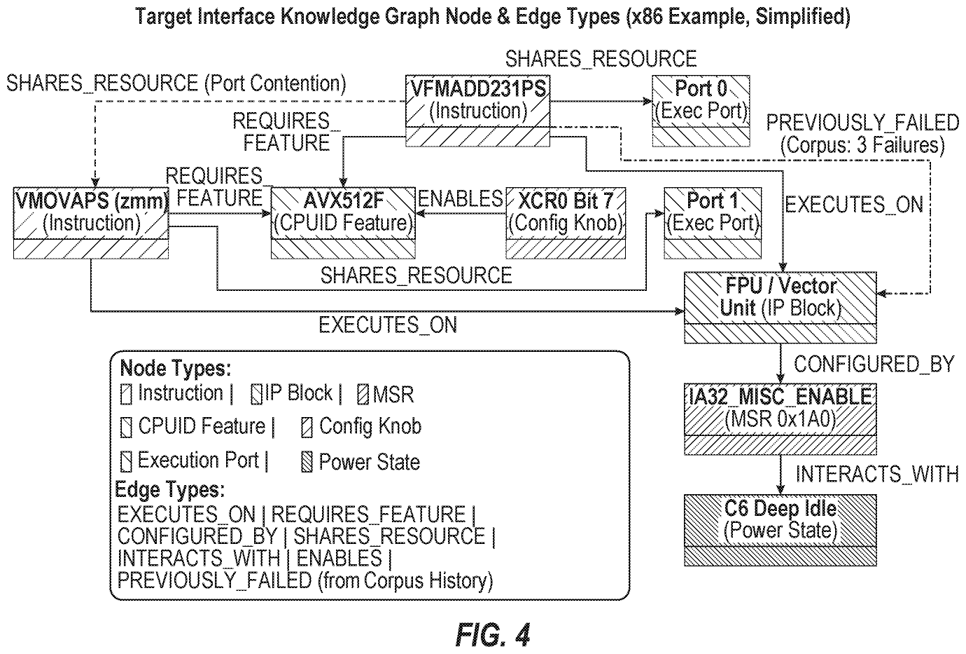

FIG. 4 illustrates nodes and edge types of one such knowledge graph, using a focused AVX-512 instruction example. Additional or more detailed semantics, such as usage constraints, architectural effects, flags/state effects, allowed exceptions, required privileges, and the like, may be included in a knowledge graph.

The example knowledge graph depicted in FIG. 4 includes seven node categories.

Instructions: individual ISA operations (e.g., VFMADD231PS, VMOVAPS with 512-bit ZMM operands).

IP Blocks: functional units on the die that execute those instructions (e.g., FPU/Vector Unit).

MSRs: model-specific registers that configure IP block behavior (e.g., IA32_MISC ENABLE at address 0x1A0).

CPUID Features: enumerated capability bits that gate instruction availability (e.g., AVX512F).

Config Knobs: software-visible control bits that enable or disable features (e.g., XCR0 bit 7, which enables ZMM state save/restore).

Execution Ports: dispatch slots within the out-of-order engine (e.g., Port 0, Port 1) that create resource contention between co-scheduled instructions.

Power States: processor idle or performance states (e.g., C6 deep idle) that interact with configuration registers and can alter silicon behavior on wake.

The example knowledge graph depicted in FIG. 4 also includes seven relationship types (edges) to connect these nodes.

EXECUTES_ON: maps an instruction to the IP block that implements it. Both VFMADD231PS and VMOVAPS execute on the FPU/Vector Unit, meaning mutations involving either instruction will stress the same silicon.

REQUIRES FEATURE: links an instruction to the CPUID feature that must be present. Both instructions require AVX512F; the generator will not emit them on a part that does not enumerate this bit.

CONFIGURED BY: connects an IP block to the MSR that governs its operation. The FPU/Vector Unit is influenced by IA32_MISC_ENABLE, which controls various hardware prefetch and feature-enable behaviors.

SHARES RESOURCE: indicates that two instructions compete for the same physical resource. VFMADD231PS dispatches to Port 0 while VMOVAPS dispatches to Port 1, but both contend for FPU register-file bandwidth. The dashed edge between the two instructions captures this implicit port contention, a dimension the generator exploits to create pipeline-stress sequences.

INTERACTS_WITH: captures cross-domain influence. IA32 MISC ENABLE interacts with C6 deep idle because configuration changes to this MSR can affect how the core behaves entering or exiting deep sleep, a common source of errata.

ENABLES: records a gating dependency. XCR0 bit 7 enables the AVX512F feature; without this knob asserted, the processor will fault on any 512-bit instruction regardless of CPUID support. This lets the generator construct “near-miss” sequences that toggle enabling state around a failure.

PREVIOUSLY FAILED: drawn from corpus history. The red edge from VFMADD231PS to the FPU/Vector Unit indicates that prior fuzzing runs recorded three failures involving this instruction on this IP block. This is the mechanism by which Mode 1 (failure-directed) biases generation: the generator preferentially selects instructions and IP blocks with high failure counts, mutates around the known failure point, and attempts to amplify coverage in that region of the graph.

The test generator may use the graph as follows. In Mode 1 (failure-directed), the test generator walks from PREVIOUSLY_FAILED edges to neighboring nodes, choosing instructions that share the same execution port, require the same feature, or are configured by the same MSR. This produces targeted mutations near known failures. In Mode 2 (exploratory), the test generator traverses the graph broadly, sampling instructions across diverse IP blocks and feature sets to maximize coverage. The graph structure ensures that mutations are architecturally valid (required features are present, config knobs are set) and physically meaningful (mutations stress related hardware, not arbitrary instruction pairs).

Various approaches can be used to determine whether a generated sequence passed or failed. This is the fundamental challenge in any automated test system, but the architecture discussed herein can use any combination of the following complementary strategies.

Differential comparison. Execute the same sequence on the Device Under Test and on a known-good reference, then compare the architectural state at completion. The reference can be a golden model, a different silicon stepping, a software emulator or simulator, or simply a different core on the same CPU. Mismatches in register values, flags, or memory contents constitute a failure signal.

Self-consistency checks. Execute the same sequence multiple times on the same target device and flag non-deterministic results. Under the ISA contract, identical instruction sequences with identical inputs must produce identical outputs. Any divergence indicates a potential silicon failure (e.g., a timing-sensitive electrical marginality that manifests intermittently).

Architectural state validation. For sequences where expected results can be computed statically, particularly arithmetic and logical operations, the generator can embed expected results into the test. This now constitutes a self-checking test.

Crash and fault detection. Machine checks (MCEs), unexpected exceptions (GP, #UD, #PF), process hangs, and watchdog timeouts are treated as immediate failure signals. These require no computation; failure is self-evident.

Soft-failure detection. Monitor sideband telemetry, including execution timing, die temperature, and power draw, during sequence execution. Sequences that produce statistically anomalous thermal spikes, power transients, or latency outliers are flagged for investigation even if they produce architecturally correct results. This captures marginal silicon behavior that a purely functional check would miss.

The test system is not restricted to a single strategy. In practice, the result checker layers these approaches: crash detection is always active, differential comparison is used when a reference is available, self-consistency is applied when it is not, and anomaly detection runs passively on all executions. The failure signal from any layer feeds into the failure domain identifier and into sequence scoring, where it influences corpus evolution.

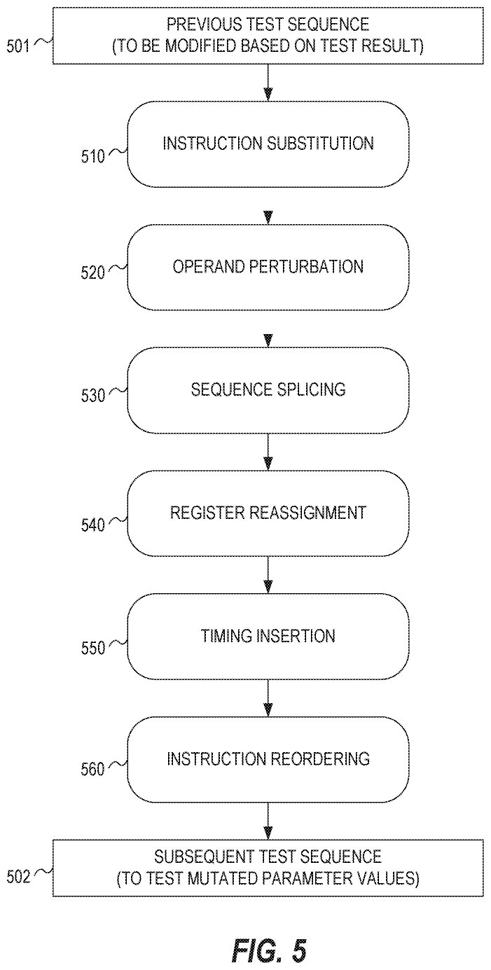

FIG. 5 depicts an example operational flow for mutating parameters in a subsequent test sequence, in connection with multi-dimensional fuzzing techniques. As an example implementation, the test generator discussed above includes capabilities to transform an existing (previous) test sequence 501 into a new (subsequent) test sequence 502 using six classes of mutation, each guided by the knowledge graph.

The previous test sequence 501 represents a test sequence that produced a test result, such as a test sequence classified as a hard failure, a soft anomaly, or a pass. One or more of the mutation strategies is applied to the previous test sequence 501 to produce the subsequent test sequence 502, which includes mutated parameter values for execution on the semiconductor device under test. The following mutation strategies 510, 520, 530, 540, 550, and 560 can be applied individually or in combination to produce the new (subsequent) test sequence 502.

Operation 510: Instruction substitution. A replacement instruction executes on the same functional unit as the replaced instruction or shares a common execution resource with the replaced instruction. For instance, this operation can replace an instruction with one that executes on the same IP block or shares the same execution port (e.g., swap VFMADD231PS for VFMADD213PS to explore adjacent opcode encodings on the same FPU data path).

Operation 520: Operand perturbation. This operation modifies an operand of an instruction of the previous test sequence, such as register indices, immediate values, or memory offsets while preserving instruction validity. Boundary values (all-ones, power-of-two, denormals for FP) are preferentially sampled.

Operation 530: Sequence splicing. The combined fragments are drawn from test sequences that exercise a common functional unit or feature set. For instance, this operation can combine fragments from two corpus sequences that stress the same IP block or feature set, creating novel instruction interleavings neither parent contained.

Operation 540: Register reassignment. This operation remaps register operands to create or break data dependencies between instructions, altering pipeline forwarding and hazard behavior without changing the instruction mix.

Operation 550: Timing insertion. This operation inserts one or more operations between operations of the previous test sequence 501 to shift relative timing among the operations. For example, this operation can inject NOPs, memory fences (MFENCE, LFENCE), or serializing instructions (CPUID) between operations to shift relative timing in the pipeline and expose race-sensitive failures.

Operation 560: Instruction Reordering. This operation permutes instruction order within dependency-legal bounds to exercise different scheduling paths through the out-of-order engine.

In Mode 1, the generator biases toward the class that produced the most recent failure. If a failure was found via timing insertion, subsequent mutations preferentially vary the type and placement of timing barriers around the failing region. In Mode 2, mutations are sampled uniformly across all six classes.

Consider the following hypothetical failure-directed fuzzing scenario. A host running screening detects an intermittent thermal warning during an AVX-512 heavy workload. The warning does not cause a hard failure, but the temperature briefly exceeds the expected range. A detection occurs (in Mode 1). The thermal warning triggers the system in failure-directed mode. The soft anomaly is classified as a thermal deviation during vector unit activity.

The faulting workload's instruction profile (AVX-512 instructions) and the thermal sensor location (core vector unit) map the anomaly to the FPU/vector IP block with high confidence. A campaign is configured with the fuzzing orchestrator for targeting the vector unit: AVX-512 instruction families are selected, XCR0 is varied to toggle AVX-512 sub-features (ZMM registers, opmask), power P-states are included to evaluate frequency/voltage combinations, and the MSR range for turbo boost and thermal control is added.

The test generator produces many (e.g., 100,000) multi-dimensional test sequences, each combining AVX-512 instructions, XCR0 configurations, P-state transitions, and thermal-related MSR values. Sequences are executed on the silicon to test. Suppose a specific sequence, for instance, a specific combination of AVX-512 VFMADD instructions with turbo boost at maximum frequency and XCR0 enabling all ZMM registers, triggers a hard hang. After reset (from the hard hang) the full state at hang is logged: instruction sequence, MSR 0x1A0 (IA32_MISC_ENABLE) value, XCR0=0xE7, P-state=max turbo, thermal status MSR values.

After initial triage (3 retries, all hang), the sequence is flagged as a confirmed new failure. Extended replay on a test bench confirms 94% reproducibility across 50 attempts. Global Federated Corpus Entry includes the following information, tagged as: IP=FPU/vector, Product=GNR, Stepping=B0, Failure=hang, Score=0.94, Config={XCR0-0xE7, P-state=max, MSR 0x1A0-0x . . . }.

The test sequence is published to the global federated corpus. Site B queries the corpus for all GNR B0 sequences with a reproducibility score above 0.8 and pulls this sequence into its screening package. An offline bundle for an external ODM release is exported, containing this sequence and 47 other proven GNR-B0 sequences. Site B reproduces the failure independently, and the corpus entry is updated with the additional reproduction data, increasing statistical confidence in the failure breadth and reproducibility score.

Corpus dashboards surface the sequence as a newly confirmed, high-reproducibility hang affecting multiple sites. A bug is filed and assigned to the relevant engineering team. Using the captured state and deterministic replay, the team reproduces the failure on their bench and identifies a firmware-level trigger. A firmware fix is developed and validated.

Following the firmware fix, the sequence is re-executed against updated firmware and the reproducibility score drops to zero, confirming the fix. Units running unpatched firmware continue to trigger the failure, providing a regression test for the fix. The mutation engine generates variants of the sequence to determine whether related failure modes remain exploitable under the patched firmware, expanding coverage around the now-known failure domain.

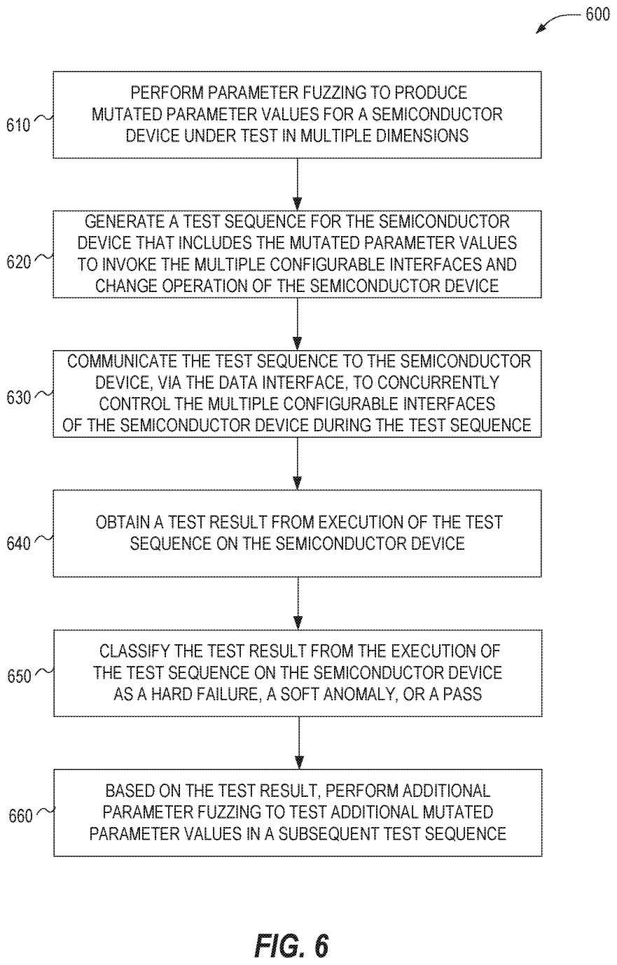

FIG. 6 illustrates a flowchart 600 of an example method for testing a semiconductor device using multi-dimensional parameter fuzzing. In one example, the operations of this method are performed by processing circuitry of a computing system that directly communicates with a semiconductor device under test through a data interface. Other implementations may involve respective computer systems or devices to separately generate and execute the test sequences.

At operation 610, the method performs parameter fuzzing to produce mutated parameter values in multiple dimensions for a semiconductor device under test. The mutated parameter values are parameter values of the semiconductor device. The multiple dimensions correspond to multiple configurable interfaces of the semiconductor device, as discussed above. The mutated parameter values provide varying combinations of parameter values that test the multiple dimensions of the semiconductor device during the test sequence.

For example, the multiple dimensions may be provided from two or more of: a use of one or more CPU instructions on the semiconductor device; a use of one or more hardware registers on the semiconductor device; a use of one or more power states on the semiconductor device; a use of one or more configuration knobs on the semiconductor device; a timing of operations performed on the semiconductor device; or a concurrency of execution of operations performed on the semiconductor device. As shown in the parameter sources in FIG. 2, the parameter fuzzing can draw mutated parameter values from any two or more of these dimensions.

Parameter fuzzing may be performed in several contexts. In one context, the parameter fuzzing is performed in connection with a failure or anomaly detection trigger from a previous test sequence. In another context, the parameter fuzzing is performed in connection with validation fuzzing that tests respective dimensions of the semiconductor device regardless of failure of a prior test sequence. In another context, the parameter fuzzing is performed in connection with federated screening of test sequences provided from other testing instances, the federated screening providing a group of known test sequences that trigger a hard failure or a soft anomaly.

At operation 620, the method generates a test sequence for the semiconductor device that includes the mutated parameter values to invoke the multiple configurable interfaces and change the operation of the semiconductor device. The test sequence is generated based on test results from prior test sequences. In some examples, the test sequence is generated based on a knowledge graph that organizes relationships among the multiple dimensions, parameter values, test sequences, and test results, and the knowledge graph includes information to track a status of a previously failed test sequence.

In some examples, the knowledge graph may include a relationship that indicates a prior failure associated with a functional unit of a failure domain, and a subsequent test sequence may be generated based on a biasing selection of additional mutated parameter values toward a parameter value associated with the failure domain. An example of the knowledge graph and its node and edge types are depicted in FIG. 4 and discussed above, where the PREVIOUSLY_FAILED relationship records the status of a previously failed test sequence, which biases generation of the test sequence toward a region associated with the prior failure. In some examples involving federated screening, the group of known (proven) test sequences is stored in a federated corpus of results from test screening at multiple test locations, and the test results from prior test sequences are provided from the federated corpus of results.

In some examples, a group of proven test sequences provided by federated screening is stored in a federated corpus of results from test screening at multiple test locations, and the federated corpus associates the group of proven test sequences with metadata tags. The metadata tags can include at least one of: an IP block identifier, a product identifier, a stock keeping unit (SKU) identifier, a CPUID signature, stepping data, severity data, reproducibility data, and configuration context data. The federated corpus of results is updated based on contributions from the test screening at the multiple test locations, as the federated corpus tracks a confidence measurement or failure breadth measurement based on outcomes of the test screening at the multiple test locations. In some examples, contributions to the federated corpus of results are screened to publish only the proven test sequences that are reproducible to trigger the hard failure or the soft anomaly. The federated corpus of results also may be maintained as a versioned corpus.

At operation 630, the method communicates or otherwise provides the test sequence to the semiconductor device, such as via the data interface, to concurrently control the multiple configurable interfaces of the semiconductor device during the test sequence. Communicating the test sequence over the data interface causes the multiple configurable interfaces, corresponding to the multiple dimensions, to be controlled together during execution of the test sequence on the semiconductor device.

At operation 640, the method obtains a test result from execution of the test sequence on the semiconductor device. The test result reflects the behavior of the semiconductor device while the multiple configurable interfaces are controlled by the test sequence.

At operation 650, the method classifies the test result from the execution of the test sequence on the semiconductor device as a hard failure, a soft anomaly, or a pass, using one or more measurements from the test result. In this context, a hard failure is a violation of an architectural state at the semiconductor device. A soft anomaly is a deviation of an operational state from an expected range at the semiconductor device. A pass is recorded when the test result is neither a hard failure nor a soft anomaly. For instance, the failure and anomaly detection classifier 230 of FIG. 2 may perform this classification, separating the pass outcome (the “Pass: No failure Detected” path) from the hard failure and soft anomaly outcomes (the “Failure/Anomaly Detected” path).

In some examples, in response to a hard failure or a soft anomaly, the method maps the hard failure or the soft anomaly to one or more suspect functional units of the semiconductor device. In an example, the one or more suspect functional units may be selected based on a failure signature of the hard failure or the soft anomaly. For instance, the one or more suspect functional units may be selected using one or more heuristics that include at least one of: an opcode of an instruction associated with the hard failure or the soft anomaly that identifies a functional unit, an address range of a hardware register associated with the hard failure or the soft anomaly that identifies a configuration domain, an exception vector or machine-check bank that identifies a hardware source, or a sensor location associated with a soft anomaly that identifies a physical functional unit. The one or more suspect functional units may also be provided as a set of candidate functional units ranked by a confidence value. The failure and anomaly detection classifier 230 may perform this mapping.

In some examples, the method extracts a set of features from the test sequence in response to the hard failure or the soft anomaly, and assigns the hard failure or the soft anomaly to a failure domain based on the extracted set of features, to establish a failure domain corresponding to a group of failures associated with a common root cause. The extracted set of features may include two or more of: a set of instruction classes present in the test sequence, a set of functional units exercised by the test sequence, a set of CPUID features used by the test sequence, a set of register file regions accessed by the test sequence, and a telemetry signature observed during execution of the test sequence. The method may compare the extracted set of features for the hard failure or the soft anomaly against a set of features for an existing failure domain, and assign the hard failure or the soft anomaly to the existing failure domain based on a measure of similarity between the extracted set of features and the set of features for the existing failure domain satisfying a similarity threshold. A subsequent test sequence may be generated based on the failure domain assigned to the hard failure or the soft anomaly, so that the subsequent test sequence includes additional mutated parameter values selected to test the failure domain.

At operation 660, the method performs, based on the test result, additional parameter fuzzing to test additional mutated parameter values in a subsequent test sequence. The type of additional parameter fuzzing depends on the classification at operation 650. In response to a pass of the test result, the method performs additional parameter fuzzing with exploratory fuzzing techniques to test additional mutated parameter values in a subsequent test sequence. In response to a hard failure or a soft anomaly of the test result, the method performs additional parameter fuzzing with failure-directed fuzzing based on the mutated parameter values to test additional mutated parameter values in a subsequent test sequence. In an example using failure-directed fuzzing, the subsequent test sequence is generated based on the failure domain assigned to the hard failure or the soft anomaly, with the additional mutated parameter values biased toward a parameter value associated with the failure domain. This corresponds to the two return paths shown in FIG. 2: the “Exploratory Fuzzing” path that returns a pass outcome to the multi-dimensional parameter space fuzzing component 210, and the “Failure-Directed Fuzzing” path that returns a hard failure or soft anomaly outcome to the same component.

Additional mutated parameter values, produced at operation 660, may be used in a subsequent test sequence, forming a feedback loop in which the test result from one test sequence informs the generation of a later test sequence. The semiconductor device tested by the method can be a central processing unit (CPU), a graphics processing unit (GPU), a System-on-Chip, or a System-in-Package, as implemented with various test harness, test system, or post-silicon validation settings.

Although the detailed description and examples here were provided with reference to a CPU/×86 implementation, the present techniques are not limited to processors. The same architecture applies to any semiconductor device or other silicon IP implementation with configurable interfaces, including GPUs, hardware accelerators, memory controllers, memory, network ASICs, custom silicon, or variations or combinations of such hardware, including System-on-Chip or System-in-Package devices. Likewise, the same architecture can be applied to pre-silicon testing environments such as RTL simulation, hardware emulation platforms, and virtual prototypes. In non-CPU contexts, “instruction sequences” generalizes to “command sequences” appropriate to the target interface (e.g., shader dispatch sequences for GPUS, transaction sequences for memory controllers, descriptor sequences for network ASICs), and “MSRs” generalizes to any device-specific configuration registers or control interfaces. The corpus data model, federated screening mechanism, and failure-directed fuzzing modes can be used regardless of the underlying target interface type.

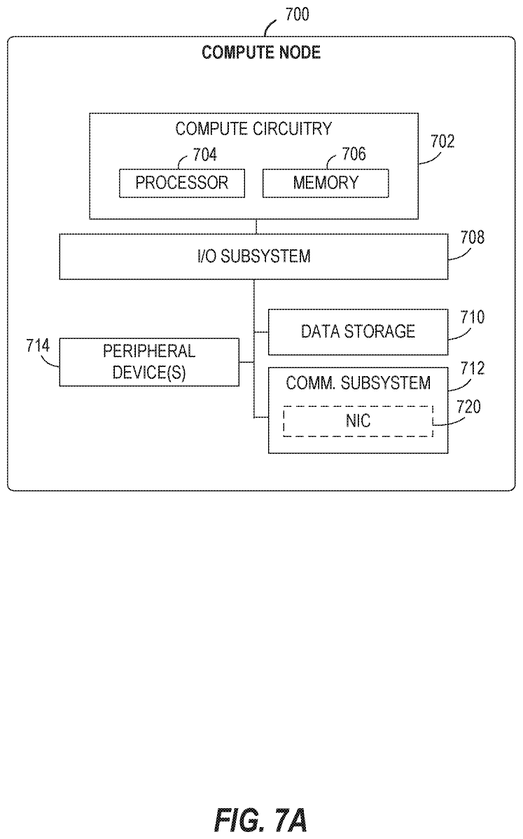

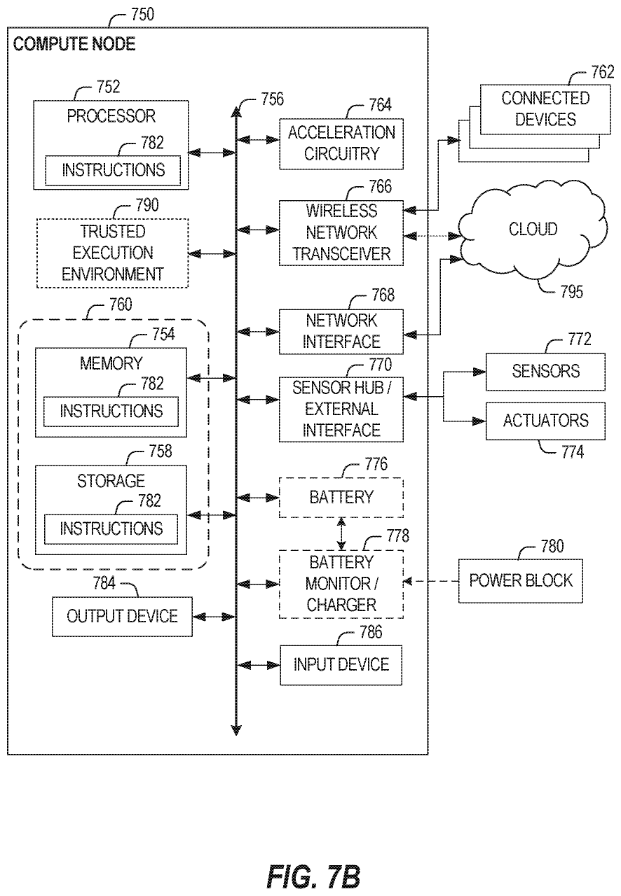

Any of the computing nodes or devices used to implement the aforementioned techniques may be implemented based on the components of a compute node as depicted in FIGS. 7A and 7B. Respective compute nodes may be embodied as a type of device, appliance, computer, or other “thing” capable of communicating with other edge, networking, or endpoint components. For example, a compute device may be embodied as a robot, a robot control system, a personal computer, a server, a mobile computing device, a smart appliance, an in-vehicle compute system (e.g., a navigation system), a self-contained device having an outer case, shell, etc., or other device or system capable of performing the described functions.

In the simplified example depicted in FIG. 7A, a compute node 700 includes a compute engine (also referred to herein as “compute circuitry”) 702, an input/output (I/O) subsystem 708, a data storage device 710, a communication circuitry 712 subsystem, and, optionally, one or more peripheral devices 714. In other examples, respective compute devices may include other or additional components, such as those typically found in a computer (e.g., a display, peripheral devices, etc.). Additionally, in some examples, one or more of the illustrative components may be incorporated in, or otherwise form a portion of, another component.

The compute node 700 may be embodied as any type of engine, device, or collection of devices capable of performing various compute functions. In some examples, the compute node 700 may be embodied as a single device such as an integrated circuit, an embedded system, a field-programmable gate array (FPGA), a system-on-a-chip (SOC), or other integrated system or device. In the illustrative example, the compute node 700 includes or is embodied as a processor 704 and a memory 706. The processor 704 may be embodied as any type of processor capable of performing the functions described herein (e.g., executing an application). For example, the processor 704 may be embodied as a multi-core processor(s), a microcontroller, a processing unit, a specialized or special-purpose processing unit, or other processor or processing/controlling circuit.

In some examples, the processor 704 may be embodied as, include, or be coupled to an FPGA, an application-specific integrated circuit (ASIC), reconfigurable hardware or hardware circuitry, or other specialized hardware to facilitate performance of the functions described herein. Also in some examples, the processor 704 may be embodied as a specialized x-processing unit (xPU) also known as a data processing unit (DPU), infrastructure processing unit (IPU), or network processing unit (NPU). Such an xPU may be embodied as a standalone circuit or circuit package, integrated within an SOC, or integrated with networking circuitry (e.g., in a SmartNIC, or enhanced SmartNIC), acceleration circuitry, storage devices, or AI hardware (e.g., GPUs or programmed FPGAs). Such an xPU may be designed to receive programming to process one or more data streams and perform specific tasks and actions for the data streams (such as hosting microservices, performing service management or orchestration, organizing or managing server or data center hardware, managing service meshes, or collecting and distributing telemetry), outside of the CPU or general-purpose processing hardware. However, it will be understood that an xPU, a SOC, a CPU, and other variations of the processor 704 may work in coordination with each other to execute many types of operations and instructions within and on behalf of the compute node 700.

The memory 706 may be embodied as any type of volatile (e.g., dynamic random access memory (DRAM), etc.) or non-volatile memory or data storage capable of performing the functions described herein. Volatile memory may be a storage medium that requires power to maintain the state of data stored by the medium. Non-limiting examples of volatile memory may include various types of random access memory (RAM), such as DRAM or static random access memory (SRAM). One particular type of DRAM that may be used in a memory module is synchronous dynamic random access memory (SDRAM).

In an example, the memory device is a block addressable memory device, such as those based on NAND or NOR technologies. A memory device may also include a three-dimensional crosspoint memory device (e.g., Intel® 3D XPoint™ memory), or other byte addressable write-in-place nonvolatile memory devices. The memory device may refer to the die itself and/or to a packaged memory product. In some examples, 3D crosspoint memory (e.g., Intel® 3D XPoint™ memory) may comprise a transistor-less stackable cross-point architecture in which memory cells sit at the intersection of word lines and bit lines and are individually addressable and in which bit storage is based on a change in bulk resistance. In some examples, all or a portion of the memory 706 may be integrated into the processor 704. The memory 706 may store various software and data used during operation, such as one or more applications, data operated on by the application(s), libraries, and drivers.

The compute circuitry 702 is communicatively coupled to other components of the compute node 700 via the I/O subsystem 708, which may be embodied as circuitry and/or components to facilitate input/output operations with the compute circuitry 702 (e.g., with the processor 704 or the main memory 706) and other components of the compute circuitry 702. For example, the I/O subsystem 708 may be embodied as, or otherwise include, memory controller hubs, input/output control hubs, integrated sensor hubs, firmware devices, communication links (e.g., point-to-point links, bus links, wires, cables, light guides, printed circuit board traces, etc.), and/or other components and subsystems to facilitate the input/output operations. In some examples, the I/O subsystem 708 may form a portion of a system-on-a-chip (SoC) and be incorporated, along with one or more of the processor 704, the memory 706, and other components of the compute circuitry 702, into the compute circuitry 702.

The one or more illustrative data storage devices 710 may be embodied as any type of devices configured for short-term or long-term storage of data, such as, for example, memory devices and circuits, memory cards, hard disk drives, solid-state drives, or other data storage devices. Individual data storage devices 710 may include a system partition that stores data and firmware code for the data storage device 710. Individual data storage devices 710 may also include one or more operating system partitions that store data files and executables for operating systems, depending on, for example, the type of compute node 700.

The communication circuitry 712 may be embodied as any communication circuit, device, or collection thereof, capable of enabling communications over a network between the compute circuitry 702 and another compute device (e.g., a gateway of an implementing computing system). The communication circuitry 712 may be configured to use one or more communication technologies (e.g., wired or wireless communications) and associated protocols (e.g., a cellular networking protocol such as a 3GPP 4G or 5G standard, a wireless local area network protocol such as IEEE 802.11/Wi-Fi®, a wireless wide area network protocol, Ethernet, Bluetooth®, Bluetooth Low Energy, an IoT protocol such as IEEE 802.15.4 or ZigBee®, low-power wide-area network (LPWAN) or low-power wide-area (LPWA) protocols, etc.) to effect such communication.

The illustrative communication circuitry 712 includes a network interface controller (NIC) 720, which may also be referred to as a host fabric interface (HFI). The NIC 720 may be embodied as one or more add-in-boards, daughter cards, network interface cards, controller chips, chipsets, or other devices that may be used by the compute node 700 to connect with another compute device (e.g., a gateway node). In some examples, the NIC 720 may be embodied as part of a system-on-a-chip (SoC) that includes one or more processors, or included on a multichip package that also contains one or more processors. In some examples, the NIC 720 may include a local processor (not shown) and/or a local memory (not shown) that are both local to the NIC 720. In such examples, the local processor of the NIC 720 may be capable of performing one or more of the functions of the compute circuitry 702 described herein. Additionally, or alternatively, in such examples, the local memory of the NIC 720 may be integrated into one or more components of the client compute node at the board level, socket level, chip level, or other levels.

Additionally, in some examples, a respective compute node 700 may include one or more peripheral devices 714. Such peripheral devices 714 may include any type of peripheral device found in a compute device or server, such as audio input devices, a display, other input/output devices, interface devices, and/or other peripheral devices, depending on the particular type of the compute node 700. In further examples, the compute node 700 may be embodied by a respective compute node (whether a client, gateway, or aggregation node) in a computing system or like forms of appliances, computers, subsystems, circuitry, or other components.

In a more detailed example, FIG. 7B illustrates a block diagram of an example of components that may be present in a computing node 750 for implementing the techniques (e.g., operations, processes, methods, and methodologies) described herein. This computing node 750 provides a closer view of the respective components of node 700 when implemented as or as part of a computing device (e.g., as a mobile device, a base station, server, gateway, etc.). The computing node 750 may include any combinations of the hardware or logical components referenced herein, and it may include or couple with any device usable with a communication network or a combination of such networks. The components may be implemented as integrated circuits (ICs), portions thereof, discrete electronic devices, or other modules, instruction sets, programmable logic or algorithms, hardware, hardware accelerators, software, firmware, or a combination thereof adapted in the computing node 750, or as components otherwise incorporated within a chassis of a larger system.

The computing node 750 may include processing circuitry in the form of a processor 752, which may be a microprocessor, a multi-core processor, a multithreaded processor, an ultra-low voltage processor, an embedded processor, an xPU/DPU/IPU/NPU, special-purpose processing unit, specialized processing unit, or other known processing elements. The processor 752 may be a part of a system on a chip (SoC) in which the processor 752 and other components are formed into a single integrated circuit, or a single package, such as the Edison™ or Galileo™ SoC boards from Intel Corporation, Santa Clara, California. As an example, the processor 752 may include an Intel® Architecture Core™ based CPU processor, such as a Quark™, an Atom™, an i3, an i5, an i7, an i9, or an MCU-class processor, or another such processor available from Intel®. However, any number of other processors may be used, such as those available from Advanced Micro Devices, Inc. (AMD®) of Sunnyvale, California, a MIPS®-based design from MIPS Technologies, Inc. of Sunnyvale, California, an ARM®-based design licensed from ARM Holdings, Ltd., or a customer thereof, or their licensees or adopters. The processors may include units such as an A5-A19 processor from Apple® Inc., a Snapdragon™ processor from Qualcomm® Technologies, Inc., or an OMAP™ processor from Texas Instruments, Inc. The processor 752 and accompanying circuitry may be provided in a single socket form factor, multiple socket form factor, or a variety of other formats, including in limited hardware configurations or configurations that include fewer than all elements shown in FIG. 7B.

The processor 752 may communicate with a system memory 754 over an interconnect 756 (e.g., a bus). Any number of memory devices may be used to provide for a given amount of system memory. As examples, the memory 754 may be random access memory (RAM) in accordance with a Joint Electron Devices Engineering Council (JEDEC) design such as the DDR or mobile DDR standards (e.g., LPDDR, LPDDR2, LPDDR3, or LPDDR4). In particular examples, a memory component may comply with a DRAM standard promulgated by JEDEC, such as JESD79F for DDR SDRAM, JESD79-2F for DDR2 SDRAM, JESD79-3F for DDR3 SDRAM, JESD79-4A for DDR4 SDRAM, JESD209 for Low Power DDR (LPDDR), JESD209-2 for LPDDR2, JESD209-3 for LPDDR3, and JESD209-4 for LPDDR4. Such standards (and similar standards) may be referred to as DDR-based standards and communication interfaces of the storage devices that implement such standards may be referred to as DDR-based interfaces. In various implementations, the individual memory devices may be of any number of different package types, such as single die package (SDP), dual die package (DDP), or quad die package (QDP). These devices, in some examples, may be directly soldered onto a motherboard to provide a lower profile solution, while in other examples, the devices are configured as one or more memory modules that in turn couple to the motherboard by a given connector. Any number of other memory implementations may be used, such as other types of memory modules, e.g., dual inline memory modules (DIMMs) of different varieties, including but not limited to microDIMMs or MiniDIMMs.

To provide for persistent storage of information, such as data, applications, operating systems, and so forth, a storage 758 may also be coupled to the processor 752 via the interconnect 756. In an example, the storage 758 may be implemented via a solid-state disk drive (SSD). Other devices that may be used for the storage 758 include flash memory cards, such as Secure Digital (SD) cards, microSD cards, extreme Digital (XD) picture cards, and the like, and Universal Serial Bus (USB) flash drives. In an example, the memory device may be or may include memory devices that use chalcogenide glass, multi-threshold level NAND flash memory, NOR flash memory, single or multi-level Phase Change Memory (PCM), a resistive memory, nanowire memory, ferroelectric transistor random access memory (FeTRAM), anti-ferroelectric memory, magnetoresistive random access memory (MRAM) memory that incorporates memristor technology, resistive memory including the metal oxide base, the oxygen vacancy base and the conductive bridge Random Access Memory (CB-RAM), or spin transfer torque (STT)-MRAM, a spintronic magnetic junction memory based device, a magnetic tunneling junction (MTJ) based device, a DW (Domain Wall) and SOT (Spin Orbit Transfer) based device, a thyristor based memory device, or a combination of any of the above, or other memory.

In low-power implementations, the storage 758 may be on-die memory or registers associated with the processor 752. However, in some examples, the storage 758 may be implemented using a micro hard disk drive (HDD). Further, any number of new technologies may be used for the storage 758 in addition to, or instead of, the technologies described, such as resistance change memories, phase change memories, holographic memories, or chemical memories, among others.

The components may communicate over the interconnect 756. The interconnect 756 may include any number of technologies, including industry standard architecture (ISA), extended ISA (EISA), peripheral component interconnect (PCI), peripheral component interconnect extended (PCIx), PCI Express (PCIe), or any number of other technologies. The interconnect 756 may be a proprietary bus, for example, used in an SoC-based system. Other bus systems may be included, such as an Inter-Integrated Circuit (I2C) interface, a Serial Peripheral Interface (SPI) interface, point-to-point interfaces, and a power bus, among others.

The interconnect 756 may couple the processor 752 to a transceiver 766, for communications with the connected devices 762. The transceiver 766 may use any number of frequencies and protocols, such as 2.4 Gigahertz (GHz) transmissions under the IEEE 802.15.4 standard, using the Bluetooth® low energy (BLE) standard, as defined by the Bluetooth® Special Interest Group, or the ZigBee® standard, among others. Any number of radios, configured for a particular wireless communication protocol, may be used for the connections to the connected devices 762. For example, a wireless local area network (WLAN) unit may be used to implement Wi-Fi® communications in accordance with the Institute of Electrical and Electronics Engineers (IEEE) 802.11 standard. In addition, wireless wide area communications, e.g., according to a cellular or other wireless wide area protocol, may occur via a wireless wide area network (WWAN) unit.

The wireless network transceiver 766 (or multiple transceivers) may communicate using multiple standards or radios for communications at different ranges. For example, the computing node 750 may communicate with close devices, e.g., within about 7 meters, using a local transceiver based on Bluetooth Low Energy (BLE), or another low-power radio, to save power. More distant connected devices 762, e.g., within about 50 meters, may be reached over ZigBee® or other intermediate power radios. Both communications techniques may take place over a single radio at different power levels or may take place over separate transceivers, for example, a local transceiver using BLE and a separate mesh transceiver using ZigBee®.

A wireless network transceiver 766 (e.g., a radio transceiver) may be included to communicate with devices or services in the cloud 795 via local or wide-area network protocols. The wireless network transceiver 766 may be a low-power wide-area (LPWA) transceiver that follows the IEEE 802.15.4, or IEEE 802.15.4g standards, among others. The computing node 750 may communicate over a wide area using LoRaWAN™ (Long Range Wide Area Network) developed by Semtech and the LoRa Alliance. The techniques described herein are not limited to these technologies but may be used with any number of other cloud transceivers that implement long-range, low-bandwidth communications, such as Sigfox, and other technologies. Further, other communications techniques, such as time-slotted channel hopping, described in the IEEE 802.15.4e specification, may be used.

Any number of other radio communications and protocols may be used in addition to the systems mentioned for the wireless network transceiver 766, as described herein. For example, the transceiver 766 may include a cellular transceiver that uses spread spectrum (SPA/SAS) communications for implementing high-speed communications. Further, any number of other protocols may be used, such as Wi-Fi® networks for medium-speed communications and provision of network communications. The transceiver 766 may include radios that are compatible with any number of 3GPP (Third Generation Partnership Project) specifications, such as Long Term Evolution (LTE) and 5th Generation (5G) communication systems, discussed in further detail at the end of the present disclosure. A network interface controller (NIC) 768 may be included to provide a wired communication to nodes of the cloud 795 or to other devices, such as the connected devices 762 (e.g., operating in a mesh). The wired communication may provide an Ethernet connection or may be based on other types of networks, such as Controller Area Network (CAN), Local Interconnect Network (LIN), DeviceNet, ControlNet, Data Highway+, PROFIBUS, or PROFINET, among many others. An additional NIC 768 may be included to enable connecting to a second network, for example, a first NIC 768 providing communications to the cloud over Ethernet, and a second NIC 768 providing communications to other devices over another type of network.

Given the variety of types of applicable communications from the device to another component or network, applicable communications circuitry used by the device may include or be embodied by any one or more of components (circuitry 764, transceiver 766, NIC 768, or interface 770). Accordingly, in various examples, applicable means for communicating (e.g., receiving, transmitting, etc.) may be embodied by such communications circuitry.

The computing node 750 may include or be coupled to acceleration circuitry 764, which may be embodied by one or more artificial intelligence (AI) accelerators, a neural compute stick, neuromorphic hardware, an FPGA, an arrangement of GPUs, an arrangement of xPUs/DPUs/IPU/NPUs, one or more SoCs, one or more CPUs, one or more digital signal processors, dedicated ASICs, or other forms of specialized processors or circuitry designed to accomplish one or more specialized tasks. These tasks may include AI processing (including machine learning, training, inferencing, and classification operations), visual data processing, network data processing, object detection, rule analysis, or the like. These tasks also may include the specific computing tasks for service management and service operations discussed elsewhere in this document.

The interconnect 756 may couple the processor 752 to a sensor hub or external interface 770 that is used to connect additional devices or subsystems. The devices may include sensors 772, such as accelerometers, level sensors, flow sensors, optical light sensors, camera sensors, temperature sensors, global navigation system (e.g., GPS) sensors, pressure sensors, barometric pressure sensors, and the like. The hub or interface 770 further may be used to connect the computing node 750 to actuators 774, such as power switches, valve actuators, an audible sound generator, a visual warning device, and the like.

In some optional examples, various input/output (I/O) devices may be present within or connected to the computing node 750. For example, a display or other output device 784 may be included to show information, such as sensor readings or actuator position. An input device 786, such as a touch screen or keypad, may be included to accept input. An output device 784 may include any number of forms of audio or visual display, including simple visual outputs such as binary status indicators (e.g., light-emitting diodes (LEDs)) and multi-character visual outputs, or more complex outputs such as display screens (e.g., liquid crystal display (LCD) screens), with the output of characters, graphics, multimedia objects, and the like being generated or produced from the operation of the computing node 750. A display or console hardware, in the context of the present system, may be used to provide output and receive input of a computing system; to manage components or services of a computing system; identify a state of a computing component or service; or to conduct any other number of management or administration functions or service use cases.

A battery 776 may power the computing node 750, although, in examples in which the computing node 750 is mounted in a fixed location, it may have a power supply coupled to an electrical grid, or the battery may be used as a backup or for temporary capabilities. The battery 776 may be a lithium-ion battery, or a metal-air battery, such as a zinc-air battery, an aluminum-air battery, a lithium-air battery, and the like.

A battery monitor/charger 778 may be included in the computing node 750 to track the state of charge (SoCh) of the battery 776, if included. The battery monitor/charger 778 may be used to monitor other parameters of the battery 776 to provide failure predictions, such as the state of health (SoH) and the state of function (SoF) of the battery 776. The battery monitor/charger 778 may include a battery monitoring integrated circuit, such as an LTC4020 or an LTC2990 from Linear Technologies, an ADT7488A from ON Semiconductor of Phoenix, Arizona, or an IC from the UCD90xxx family from Texas Instruments of Dallas, TX. The battery monitor/charger 778 may communicate the information on the battery 776 to the processor 752 over the interconnect 756. The battery monitor/charger 778 may also include an analog-to-digital (ADC) converter that enables the processor 752 to directly monitor the voltage of the battery 776 or the current flow from the battery 776. The battery parameters may be used to determine actions that the computing node 750 may perform, such as transmission frequency, mesh network operation, sensing frequency, and the like.

A power block 780, or other power supply coupled to a grid, may be coupled with the battery monitor/charger 778 to charge the battery 776. In some examples, the power block 780 may be replaced with a wireless power receiver to obtain the power wirelessly, for example, through a loop antenna in the computing node 750. A wireless battery charging circuit, such as an LTC4020 chip from Linear Technologies of Milpitas, California, among others, may be included in the battery monitor/charger 778. The specific charging circuits may be selected based on the size of the battery 776, and thus, the current required. The charging may be performed using the Airfuel standard promulgated by the Airfuel Alliance, the Qi wireless charging standard promulgated by the Wireless Power Consortium, or the Rezence charging standard, promulgated by the Alliance for Wireless Power, among others.

The storage 758 may include instructions 782 in the form of software, firmware, or hardware commands to implement the techniques described herein. Although such instructions 782 are shown as code blocks included in the memory 754 and the storage 758, it may be understood that any of the code blocks may be replaced with hardwired circuits, for example, built into an application-specific integrated circuit (ASIC).

In an example, the instructions 782 provided via the memory 754, the storage 758, or the processor 752 may be embodied as a non-transitory, machine-readable medium 760 (also referred to as a device-readable medium or storage medium) including code to direct the processor 752 to perform electronic operations in the computing node 750. The processor 752 may access the non-transitory, machine-readable medium 760 over the interconnect 756. For instance, the non-transitory, machine-readable medium 760 may be embodied by devices described for the storage 758 or may include specific storage units such as optical disks, flash drives, or any number of other hardware devices. The non-transitory, machine-readable medium 760 may include instructions to direct the processor 752 to perform a specific sequence or flow of actions, for example, as described with respect to the flowchart(s) and block diagram(s) of operations and functionality depicted above. As used herein, the terms “machine-readable medium” and “computer-readable medium” are interchangeable.

Also in a specific example, the instructions 782 on the processor 752 (separately, or in combination with the instructions 782 of the machine-readable medium 760) may configure execution or operation of a trusted execution environment (TEE) 790. In an example, the TEE 790 operates as a protected area accessible to the processor 752 for secure execution of instructions and secure access to data. Various implementations of the TEE 790, and an accompanying secure area in the processor 752 or the memory 754 may be provided, for instance, through use of Intel® Software Guard Extensions (SGX) or ARM® TrustZone® hardware security extensions, Intel® Management Engine (ME), or Intel® Converged Security Manageability Engine (CSME). Other aspects of security hardening, hardware roots-of-trust, and trusted or protected operations may be implemented in the computing node 750 through the TEE 790 and the processor 752.

In further examples, a machine-readable medium also includes any tangible medium that is capable of storing, encoding, or carrying instructions for execution by a machine and that causes the machine to perform any one or more of the methodologies of the present disclosure or that is capable of storing, encoding, or carrying data structures utilized by or associated with such instructions. A “machine-readable medium” thus may include, but is not limited to, solid-state memories, and optical and magnetic media. Specific examples of machine-readable media include non-volatile memory, including, but not limited to, by way of example, semiconductor memory devices (e.g., electrically programmable read-only memory (EPROM), electrically erasable programmable read-only memory (EEPROM)) and flash memory devices; magnetic disks such as internal hard disks and removable disks; magneto-optical disks; and CD-ROM and DVD-ROM disks. The instructions embodied by a machine-readable medium may further be transmitted or received over a communications network using a transmission medium via a network interface device utilizing any one of a number of transfer protocols (e.g., Hypertext Transfer Protocol (HTTP)).

A machine-readable medium may be provided by a storage device or other apparatus that is capable of hosting data in a non-transitory format. In an example, information stored or otherwise provided on a machine-readable medium may be representative of instructions, such as instructions themselves or a format from which the instructions may be derived. This format from which the instructions may be derived may include source code, encoded instructions (e.g., in compressed or encrypted form), packaged instructions (e.g., split into multiple packages), or the like. The information representative of the instructions in the machine-readable medium may be processed by processing circuitry into the instructions to implement any of the operations discussed herein. For example, deriving the instructions from the information (e.g., processing by the processing circuitry) may include: compiling (e.g., from source code, object code, etc.), interpreting, loading, organizing (e.g., dynamically or statically linking), encoding, decoding, encrypting, decrypting, packaging, unpackaging, or otherwise manipulating the information into the instructions.

In an example, the derivation of the instructions may include assembly, compilation, or interpretation of the information (e.g., by the processing circuitry) to create the instructions from some intermediate or preprocessed format provided by the machine-readable medium. The information, when provided in multiple parts, may be combined, unpacked, and modified to create the instructions. For example, the information may be in multiple compressed source code packages (or object code, or binary executable code, etc.) on one or several remote servers. The source code packages may be encrypted when in transit over a network and decrypted, uncompressed, assembled (e.g., linked) if necessary, and compiled or interpreted (e.g., into a library, stand-alone executable, etc.) at a local machine, and executed by the local machine.

It should be understood that the functional units or capabilities described in this specification may have been referred to or labeled as components or modules, in order to more particularly emphasize their implementation independence. Such components may be embodied by any number of software or hardware forms. For example, a component or module may be implemented as a hardware circuit comprising custom very-large-scale integration (VLSI) circuits or gate arrays, off-the-shelf semiconductors such as logic chips, transistors, or other discrete components. A component or module may also be implemented in programmable hardware devices such as field-programmable gate arrays, programmable array logic, programmable logic devices, or the like. Components or modules may also be implemented in software for execution by various types of processors. An identified component or module of executable code may, for instance, comprise one or more physical or logical blocks of computer instructions, which may, for instance, be organized as an object, procedure, or function. Nevertheless, the executables of an identified component or module need not be physically located together but may comprise disparate instructions stored in different locations that, when joined logically together (e.g., including over a wire, over a network, using one or more platforms, wirelessly, via a software component, or the like), comprise the component or module and achieve the stated purpose for the component or module.

Indeed, a component or module of executable code may be a single instruction, or many instructions, and may even be distributed over several different code segments, among different programs, and across several memory devices or processing systems. In particular, some aspects of the described process (such as code rewriting and code analysis) may take place on a different processing system (e.g., in a computer in a data center) than that in which the code is deployed (e.g., in a computer embedded in a sensor or robot). Similarly, operational data may be identified and illustrated herein within components or modules and may be embodied in any suitable form and organized within any suitable type of data structure. The operational data may be collected as a single data set or may be distributed over different locations, including over different storage devices, and may exist, at least partially, merely as electronic signals on a system or network. The components or modules may be passive or active, including agents operable to perform desired functions.

Additional examples of the presently described method, system, and device embodiments include the following non-limiting implementations provided in the claims and/or drawings. Each of the following non-limiting examples may stand on its own or may be combined in any permutation or combination with any one or more of the other examples provided below or throughout the present disclosure.

Example 1 is a method, including: performing parameter fuzzing to produce mutated parameter values in multiple dimensions for a semiconductor device under test, the multiple dimensions corresponding to multiple configurable interfaces of the semiconductor device; generating a test sequence for the semiconductor device, the test sequence including the mutated parameter values to invoke the multiple configurable interfaces and change operation of the semiconductor device, wherein the test sequence is generated based on at least one of: test results from prior test sequences, mutated parameter values, a seed test sequence, a constraint, or a template; communicating the test sequence to the semiconductor device, via a data interface to the semiconductor device, to concurrently control the multiple configurable interfaces on the semiconductor device during the test sequence; and obtaining a test result from execution of the test sequence on the semiconductor device.

In Example 2, the subject matter of Example 1 optionally includes: classifying the test result from the execution of the test sequence on the semiconductor device as a hard failure, a soft anomaly, or a pass, using one or more measurements from the test result, wherein a hard failure comprises a violation of an architectural state at the semiconductor device, and wherein a soft anomaly comprises a deviation of an operational state from an expected range at the semiconductor device.

In Example 3, the subject matter of Example 2 optionally includes: in response to a pass of the test result, performing additional parameter fuzzing with exploratory fuzzing techniques to test additional mutated parameter values in a subsequent test sequence; and in response to a hard failure or a soft anomaly of the test result, performing additional parameter fuzzing with failure-directed fuzzing based on the mutated parameter values to test additional mutated parameter values in a subsequent test sequence.

In Example 4, the subject matter of Example 2 optionally includes: mapping the hard failure or the soft anomaly of the test result to one or more suspect functional units of the semiconductor device, the one or more suspect functional units selected based on a failure signature of the hard failure or the soft anomaly.

In Example 5, the subject matter of Example 4 optionally includes subject matter where the one or more suspect functional units are selected using one or more heuristics that include at least one of: an opcode of an instruction associated with the hard failure or the soft anomaly that identifies a functional unit, an address range of a hardware register associated with the hard failure or the soft anomaly that identifies a configuration domain, an exception vector or machine-check bank that identifies a hardware source, or a sensor location associated with a soft anomaly that identifies a physical functional unit.

In Example 6, the subject matter of Example 4 optionally includes subject matter where the one or more suspect functional units are provided as a set of candidate functional units ranked by a confidence value.

In Example 7, the subject matter of Example 2 optionally includes extracting a set of features from the test sequence in response to the hard failure or the soft anomaly; and assigning the hard failure or the soft anomaly to a failure domain based on the extracted set of features, the failure domain corresponding to a group of failures associated with a common root cause.

In Example 8, the subject matter of Example 7 optionally includes subject matter where the extracted set of features includes two or more of: a set of instruction classes present in the test sequence, a set of functional units exercised by the test sequence, a set of CPUID features used by the test sequence, a set of register file regions accessed by the test sequence, and a telemetry signature observed during execution of the test sequence.

In Example 9, the subject matter of Example 7 optionally includes comparing the extracted set of features for the hard failure or the soft anomaly against a set of features for an existing failure domain; and assigning the hard failure or the soft anomaly to the existing failure domain based on a measure of similarity between the extracted set of features and the set of features for the existing failure domain satisfying a similarity threshold.

In Example 10, the subject matter of Example 7 optionally includes subject matter where a subsequent test sequence is generated based on the failure domain assigned to the hard failure or the soft anomaly, the subsequent test sequence including additional mutated parameter values selected to test the failure domain.

In Example 11, the subject matter of Example 10 optionally includes subject matter where the subsequent test sequence is further generated based on a biasing selection of the additional mutated parameter values toward a parameter value associated with the failure domain.

In Example 12, the subject matter of Example 10 optionally includes subject matter where the subsequent test sequence is further generated based on a knowledge graph that organizes relationships among the multiple dimensions, parameter values, test sequences, and/or test results, and wherein the knowledge graph includes a relationship that indicates a prior failure associated with a functional unit of the failure domain.

In Example 13, the subject matter of any one or more of Examples 1-12 optionally includes subject matter where the mutated parameter values provide varying combinations of parameter values that test the multiple dimensions of the semiconductor device during the test sequence, wherein the multiple dimensions are provided from two or more of: a use of one or more CPU instructions on the semiconductor device; a use of one or more hardware registers on the semiconductor device; a use of one or more power states on the semiconductor device; a use of one or more configuration knobs on the semiconductor device; a timing of operations performed on the semiconductor device; or a concurrency of execution of operations performed on the semiconductor device.

In Example 14, the subject matter of any one or more of Examples 1-13 optionally includes subject matter where the test sequence is generated based on a knowledge graph that organizes relationships among the multiple dimensions, parameter values, test sequences, and/or test results, and wherein the knowledge graph includes information to track a status of a previously failed test sequence.

In Example 15, the subject matter of any one or more of Examples 1-14 optionally includes subject matter where the parameter fuzzing is performed in connection with a failure or anomaly detection trigger from a previous test sequence.

In Example 16, the subject matter of any one or more of Examples 1-15 optionally includes subject matter where the parameter fuzzing is performed in connection with validation fuzzing to test respective dimensions of the semiconductor device, regardless of failure of a prior test sequence.

In Example 17, the subject matter of any one or more of Examples 1-16 optionally includes subject matter where the parameter fuzzing is performed in connection with federated screening of test sequences provided from other testing instances, the federated screening providing a group of proven (e.g., previously executed and evaluated) test sequences that trigger a hard failure or a soft anomaly, wherein a hard failure comprises a violation of an architectural state at the semiconductor device, and wherein a soft anomaly comprises a deviation of an operational state from an expected range at the semiconductor device.

In Example 18, the subject matter of Example 17 optionally includes subject matter where the group of proven test sequences is stored in a federated corpus of results from test screening at multiple test locations, and wherein the test results from prior test sequences are provided from the federated corpus of results.

In Example 19, the subject matter of Example 18 optionally includes subject matter where the federated corpus associates the group of proven test sequences with metadata tags, the metadata tags including at least one of: an IP block identifier, a product identifier, a stock keeping unit (SKU) identifier, a CPUID signature, stepping data, severity data, reproducibility data, and configuration context data.

In Example 20, the subject matter of Example 18 optionally includes subject matter where the federated corpus of results is updated based on contributions from the test screening at the multiple test locations, and wherein the federated corpus of results tracks a confidence measurement or failure breadth measurement based on outcomes of the test screening at the multiple test locations.

In Example 21, the subject matter of Example 18 optionally includes subject matter where contributions to the federated corpus of results are screened to publish only the proven test sequences that are reproducible to trigger the hard failure or the soft anomaly.

In Example 22, the subject matter of Example 18 optionally includes subject matter where the federated corpus of results is maintained as a versioned corpus.

In Example 23, the subject matter of any one or more of Examples 1-22 optionally includes subject matter where the semiconductor device is a central processing unit (CPU), a graphics processing unit (GPU), a System-on-Chip, or a System-in-Package.

Example 24 is a system, comprising: a data interface to communicate with a semiconductor device under test; and processing circuitry configured to perform any one or more of Examples 1-23.

Example 25 is a test system, comprising: a semiconductor device under test; a data interface to communicate with a semiconductor device under test; and processing circuitry configured to implement or control a test harness to perform any one or more of Examples 1-23.

Example 26 is a device, comprising: processing circuitry; and a memory device including instructions embodied thereon, wherein the instructions, which when executed by the processing circuitry, configure the processing circuitry to perform operations for configuring or operating a computer with multi-dimensional hardware fuzzing of a semiconductor device under test, in accordance with Examples 1 to 23 or other examples disclosed herein.

Example 27 is a method, comprising a plurality of operations executed with a processor and memory of a device, to perform operations for configuring or operating a computer with multi-dimensional hardware fuzzing of a semiconductor device under test, in accordance with Examples 1 to 23 or other examples disclosed herein.

Example 28 is a non-transitory machine-readable storage medium including instructions, wherein the instructions, when executed by a processing circuitry of a device, cause the processing circuitry to perform operations for configuring or operating a computer with multi-dimensional hardware fuzzing of a semiconductor device under test, in accordance with Examples 1 to 23 or other examples disclosed herein.

Example 29 is an apparatus, comprising respective means for configuring or performing multi-dimensional hardware fuzzing of a semiconductor device under test, in accordance with Examples 1 to 23 or other examples disclosed herein.

Example 30 is a data management system, comprising a database and respective data storage devices for configuring or performing multi-dimensional hardware fuzzing of a semiconductor device under test, in accordance with Examples 1 to 10 or other examples disclosed herein.

Example 31 is a test management system, comprising a database and a test orchestration system for configuring or performing multi-dimensional hardware fuzzing of multiple semiconductor devices under test, in accordance with Examples 1 to 23 or other examples disclosed herein.

Example 32 is a network comprising respective devices and device communication mediums for performing any of the operations or techniques discussed herein, in accordance with Examples 1 to 23 or other examples disclosed herein.

Example 33 is a system comprising respective components arranged or configured to perform any of the operations or techniques discussed herein, in accordance with Examples 1 to 32 or other examples disclosed herein.

Example 34 is a method, performed using circuitry of a computing device, arranged or configured to perform any of the operations or techniques discussed herein, in accordance with Examples 1 to 32 or other examples disclosed herein.

Although these implementations have been described with reference to specific exemplary aspects, it will be evident that various modifications and changes may be made to these aspects without departing from the broader scope of the present disclosure. Accordingly, the specification and drawings are to be regarded in an illustrative rather than a restrictive sense. The accompanying drawings that form a part hereof show, by way of illustration, and not of limitation, specific aspects in which the subject matter may be practiced. The aspects illustrated are described in sufficient detail to enable those skilled in the art to practice the teachings disclosed herein. Other aspects may be utilized and derived therefrom, such that structural and logical substitutions and changes may be made without departing from the scope of this disclosure. This Detailed Description, therefore, is not to be taken in a limiting sense, and the scope of various aspects is defined only by the appended claims, along with the full range of equivalents to which such claims are entitled.

Such aspects of the inventive subject matter may be referred to herein, individually and/or collectively, merely for convenience and without intending to voluntarily limit the scope of this application to any single aspect or inventive concept if more than one is in fact disclosed. Thus, although specific aspects have been illustrated and described herein, it should be appreciated that any arrangement calculated to achieve the same purpose may be substituted for the specific aspects shown. This disclosure is intended to cover any and all adaptations or variations of various aspects. Combinations of the above aspects and other aspects not specifically described herein will be apparent to those of skill in the art upon reviewing the above description.

Method examples described herein may be machine or computer-implemented at least in part. Some examples may include a computer-readable medium or machine-readable medium encoded with instructions operable to configure an electronic device to perform methods as described in the above examples. An implementation of such methods may include code, such as microcode, assembly language code, a higher-level language code, or the like. Such code may include computer-readable instructions for performing various methods. The code may form portions of computer program products. Further, in an example, the code may be tangibly stored on one or more volatile, non-transitory, or non-volatile tangible computer-readable media, such as during execution or at other times. Examples of these tangible computer-readable media may include, but are not limited to, hard disks, removable magnetic disks, removable optical disks (e.g., compact disks and digital video disks), magnetic cassettes, memory cards or sticks, random access memories (RAMs), read-only memories (ROMs), and the like.

What is claimed is:

1. A computing system, comprising:
a data interface to communicate with a semiconductor device under test; and
processing circuitry configured to:
perform parameter fuzzing to produce mutated parameter values in multiple dimensions for the semiconductor device, the multiple dimensions corresponding to multiple configurable interfaces of the semiconductor device;
generate a test sequence for the semiconductor device, the test sequence including the mutated parameter values to invoke the multiple configurable interfaces and change operation of the semiconductor device, wherein the test sequence is generated based on test results from prior test sequences;
communicate the test sequence to the semiconductor device, via the data interface, to concurrently control the multiple configurable interfaces on the semiconductor device during the test sequence; and
obtain a test result from execution of the test sequence on the semiconductor device.

2. The computing system of claim 1, the processing circuitry further configured to:
classify the test result from the execution of the test sequence on the semiconductor device as a hard failure, a soft anomaly, or a pass, using one or more measurements from the test result,
wherein a hard failure comprises a violation of an architectural state at the semiconductor device, and wherein a soft anomaly comprises a deviation of an operational state from an expected range at the semiconductor device.

3. The computing system of claim 2, wherein the processing circuitry is further configured to:
in response to a pass of the test result, perform additional parameter fuzzing with exploratory fuzzing techniques to test additional mutated parameter values in a subsequent test sequence; and
in response to a hard failure or a soft anomaly of the test result, perform additional parameter fuzzing with failure-directed fuzzing based on the mutated parameter values to test additional mutated parameter values in a subsequent test sequence.

4. The computing system of claim 2, wherein the processing circuitry is further configured to:
map the hard failure or the soft anomaly of the test result to one or more suspect functional units of the semiconductor device, the one or more suspect functional units selected based on a failure signature of the hard failure or the soft anomaly.

5. The computing system of claim 2, wherein the processing circuitry is further configured to:
extract a set of features from the test sequence in response to the hard failure or the soft anomaly; and
assign the hard failure or the soft anomaly to a failure domain based on the extracted set of features, the failure domain corresponding to a group of failures associated with a common root cause.

6. The computing system of claim 1, wherein the mutated parameter values provide varying combinations of parameter values that test the multiple dimensions of the semiconductor device during the test sequence, and wherein the multiple dimensions are provided from two or more of:
a use of one or more CPU instructions on the semiconductor device;
a use of one or more hardware registers on the semiconductor device;
a use of one or more power states on the semiconductor device;
a use of one or more configuration knobs on the semiconductor device;
a timing of operations performed on the semiconductor device; or
a concurrency of execution of operations performed on the semiconductor device.

7. The computing system of claim 1, wherein the test sequence is generated based on a knowledge graph that organizes relationships among the multiple dimensions, parameter values, test sequences, and test results, and wherein the knowledge graph includes information to track a status of a previously failed test sequence.

8. The computing system of claim 1, wherein the parameter fuzzing is performed in connection with:
a failure or anomaly detection trigger from a previous test sequence;
validation fuzzing to test respective dimensions of the semiconductor device regardless of failure of a prior test sequence; or
federated screening of test sequences provided from other testing instances, wherein the federated screening provides a group of proven test sequences that trigger a hard failure or a soft anomaly, and wherein a hard failure comprises a violation of an architectural state at the semiconductor device, and wherein a soft anomaly comprises a deviation of an operational state from an expected range at the semiconductor device.

9. The computing system of claim 8, wherein the group of proven test sequences are stored in a federated corpus of results from test screening at multiple test locations, and wherein the test results from prior test sequences are provided from the federated corpus of results.

10. The computing system of claim 1, wherein the semiconductor device is a central processing unit (CPU), a graphics processing unit (GPU), a System-on-Chip, or a System-in-Package.

11. A non-transitory machine-readable storage medium comprising instructions that, when executed by processing circuitry of a computing system, cause the processing circuitry to perform operations that:
perform parameter fuzzing to produce mutated parameter values in multiple dimensions for a semiconductor device under test, the multiple dimensions corresponding to multiple configurable interfaces of the semiconductor device;
generate a test sequence for the semiconductor device, the test sequence including the mutated parameter values to invoke the multiple configurable interfaces and change operation of the semiconductor device, wherein the test sequence is generated based on test results from prior test sequences;
provide the test sequence to the semiconductor device, to concurrently control the multiple configurable interfaces on the semiconductor device during the test sequence; and
obtain a test result from execution of the test sequence on the semiconductor device.

12. The non-transitory machine-readable storage medium of claim 11, wherein the instructions further cause the processing circuitry to perform operations that:
classify the test result from the execution of the test sequence on the semiconductor device as a hard failure, a soft anomaly, or a pass, using one or more measurements from the test result,
wherein a hard failure comprises a violation of an architectural state at the semiconductor device, and wherein a soft anomaly comprises a deviation of an operational state from an expected range at the semiconductor device.

13. The non-transitory machine-readable storage medium of claim 12, wherein the instructions further cause the processing circuitry to perform operations that:
in response to a pass of the test result, perform additional parameter fuzzing with exploratory fuzzing techniques to test additional mutated parameter values in a subsequent test sequence; and
in response to a hard failure or a soft anomaly of the test result, perform additional parameter fuzzing with failure-directed fuzzing based on the mutated parameter values to test additional mutated parameter values in a subsequent test sequence.

14. The non-transitory machine-readable storage medium of claim 11, wherein the mutated parameter values provide varying combinations of parameter values that test the multiple dimensions of the semiconductor device during the test sequence, and wherein the multiple dimensions are provided from two or more of:
a use of one or more CPU instructions on the semiconductor device;
a use of one or more hardware registers on the semiconductor device;
a use of one or more power states on the semiconductor device;
a use of one or more configuration knobs on the semiconductor device;
a timing of operations performed on the semiconductor device; or
a concurrency of execution of operations performed on the semiconductor device.

15. The non-transitory machine-readable storage medium of claim 11, wherein the test sequence is generated based on a knowledge graph that organizes relationships among the multiple dimensions, parameter values, test sequences, and test results, and wherein the knowledge graph includes information to track a status of a previously failed test sequence.

16. A method, performed with a plurality of operations executed with at least one processor and memory of a computing system, the method comprising:
performing parameter fuzzing to produce mutated parameter values in multiple dimensions for a semiconductor device under test, the multiple dimensions corresponding to multiple configurable interfaces of the semiconductor device;
generating a test sequence for the semiconductor device, the test sequence including the mutated parameter values to invoke the multiple configurable interfaces and change operation of the semiconductor device, wherein the test sequence is generated based on test results from prior test sequences;
executing the test sequence on the semiconductor device, to concurrently control the multiple configurable interfaces on the semiconductor device during the test sequence; and
obtaining a test result from the execution of the test sequence on the semiconductor device.

17. The method of claim 16, further comprising:
classifying the test result from the execution of the test sequence on the semiconductor device as a hard failure, a soft anomaly, or a pass, using one or more measurements from the test result,
wherein a hard failure comprises a violation of an architectural state at the semiconductor device, and wherein a soft anomaly comprises a deviation of an operational state from an expected range at the semiconductor device.

18. The method of claim 17, further comprising:
in response to a pass of the test result, performing additional parameter fuzzing with exploratory fuzzing techniques to test additional mutated parameter values in a subsequent test sequence; and
in response to a hard failure or a soft anomaly of the test result, performing additional parameter fuzzing with failure-directed fuzzing based on the mutated parameter values to test additional mutated parameter values in a subsequent test sequence.

19. The method of claim 16, wherein the mutated parameter values provide varying combinations of parameter values that test the multiple dimensions of the semiconductor device during the test sequence, and wherein the multiple dimensions are provided from two or more of:
a use of one or more CPU instructions on the semiconductor device;
a use of one or more hardware registers on the semiconductor device;
a use of one or more power states on the semiconductor device;
a use of one or more configuration knobs on the semiconductor device;
a timing of operations performed on the semiconductor device; or
a concurrency of execution of operations performed on the semiconductor device.

20. The method of claim 16, wherein the test sequence is generated based on a knowledge graph that organizes relationships among the multiple dimensions, parameter values, test sequences, and test results, and wherein the knowledge graph includes information to track a status of a previously failed test sequence.
